(19) United States
(12) Patent Application Publication
(10) Pub. No.: US 2005/0007170 A1
(43) Pub. Date: Jan. 13, 2005

(54) Asynchronous control circuit and semiconductor integrated circuit device

(75) Inventors: Shigeru Nakahara, Tokyo (JP); Keiichi Higeta, Tokyo (JP); Takahiro Kawata, Tokyo (JP)

Correspondence Address: MILES & STOCKBRIDGE PC, 1751 PINNACLE DRIVE, SUITE 500, MCLEAN, VA, 22102-3833, US

(73) Assignee: Hitachi, Ltd.

(21) Appl. No.: 10/885,018

(22) Filed: Jul. 7, 2004

(30) Foreign Application Priority Data
Jul. 9, 2003 (JP) 2003-272549
Apr. 27, 2004 (JP) 2004-131238

(51) Int. Cl. H03K 3/037

(52) U.S. Cl. 327/199

(57) ABSTRACT

An asynchronous control circuit and a semiconductor integrated circuit achieving asynchronous operation and no limitation on the number of ports are offered. In an asynchronous control circuit, by being activated corresponding to at least one access request by acknowledging a plurality of access request signals generated asynchronously to each other and a plurality of input signals corresponding to each of the above-mentioned plurality of access requests, selecting one access request from one or more access requests in the activation mode, acknowledging an input signal corresponding thereto, transmitting the input signal to a memory, acknowledging the input signal corresponding to a non-executed access request after the end the operation corresponding to the input signal, and accessing the aforementioned memory circuit.

### CLAIM OF PRIORITY

The present application claims priority from Japanese application JP 2003-272549 filed on Jul. 9, 2003, and Japanese application JP 2004-131238 filed on Apr. 27, 2004, the contents of which are hereby incorporated by reference into this application.

### FIELD OF INVENTION

The present invention relates to an asynchronous control circuit and a semiconductor integrated circuit device and, for instance, to an effective method for use in circuit control technology accessing asynchronously a 1 port memory circuit from a plurality of ports.

### BACKGROUND OF THE INVENTION

The area of a multi-port SRAM (static type random access memory) becomes very large compared to a 1 port SRAM because each port in the memory cell needs an access transistor, word line and bit line. Then, U.S. Pat. No. 6,625,686 (JP-A 57775/2000) proposed that a synchronous pseudo-multiport SRAM in which the function of an N port memory is artificially achieved by accessing the 1 port SRAM core N times. On the other hand, U.S. Pat. No. 6,078,527 (JP-A 30460/2000) proposed an asynchronous type dual port SRAM in which each of the two ports uses a different clock, and the timing between the clocks was selected to be arbitrary.

### SUMMERY OF THE INVENTION

As described above, the multi-port SRAM needs the same number of access transistors as number of ports in a memory cell; therefore, its area becomes larger than that of a 1 port SRAM. Additionally, design man-hours are not much different from designing a totally different memory core. On the other hand, in a synchronous pseudo-multiport SRAM disclosed in patent document 1, because it is one in which a common clock is used between ports, it is impossible to achieve asynchronous operation between the ports, such as accessing memory with a clock of a different frequency for each port. In an asynchronous type dual port SRAM disclosed in patent document 2, because a phase-comparison circuit is used to select which of two ports demands early memory access, the number of ports is limited, and it is impossible to achieve asynchronous operation with three, four, or more ports.

It is an object of the present invention to provide an asynchronous control circuit and a semiconductor integrated circuit device containing it. It is another object of the present invention to provide an asynchronous control circuit which is convenient to use and can be built in a signal processing system with flexibility. Also an object of the invention is to provide a semiconductor integrated circuit device comprising a synchronizing circuit which aims at speeding-up and can form a logic output without metastable states. The aforementioned and other objects and new features of the invention will be apparent from the following description and accompanying drawings of the specification.

An outline of the representative items of the inventions disclosed in this patent will be briefly described as follows. That is,
a) activating as an asynchronous control circuit according to at least one access signal by acknowledging a plurality of access request signals generated asynchronously from each other and a plurality of input signals corresponding to the abovementioned plurality of access signals,
b) selecting one access request from one or more access requests in the activation state,
c) acknowledging the input signal corresponding to it, and transmitting the proper input signal to the circuit function block executing a predetermined operation,
d) acknowledging the input signal corresponding to the unexecuted access request after completing the operation corresponding to the proper input signal.

An asynchronous control circuit and memory circuit is installed in a semiconductor integrated circuit, wherein the above-mentioned asynchronous control circuit activates according to at least one access request by acknowledging a plurality of access request signals generated asynchronously from each other and a plurality of input signals corresponding to each of the above-mentioned plurality of access request signals, one access request is selected from one or more access requests in the activation state, the input signal corresponding to it is acknowledged, the proper input signal is transmitted to the above-mentioned memory circuit, and the input signal corresponding to the unexecuted access request is acknowledged after the end of operation corresponding to the proper input signal.

As a synchronizing circuit formed on a semiconductor integrated circuit, it is set so that a pair of output signals of a first latch circuit acknowledging the asynchronous input signal and clock signal have an offset voltage in the metastable state; the offset voltage of the above-mentioned output signal is amplified by an amplifier circuit operated by the delay signal of the above-mentioned clock signal, and the output signal synchronized by the above-mentioned clock signal is obtained.

A small area and asynchronous control operation without regulating the number of ports can be achieved, and the chip performance can be improved. The design data for existing 1 port SRAMs, etc. can be used; thereby, the design man-hours can be reduced. A logic output signal can be formed, which makes it possible to speed-up and have no metastable states.

### BRIEF DESCRIPTION OF THE DRAWING

FIG. 1 is a concept diagram illustrating an example of an asynchronous type pseudo-multiport memory according to the present invention;

FIG. 2 is a timing chart to explain the clock competitive relationship required by the asynchronous control circuit shown in FIG. 1;

FIG. 3 is a basic block diagram illustrating an embodiment of an asynchronous type pseudo-multiport memory according to the present invention;

FIG. 4 is a simple timing chart to explain an operation of an asynchronous type pseudo-multiport memory according to the present invention;

FIG. 5 is a basic block diagram illustrating an embodiment of an asynchronous type pseudo-multiport memory according to the present invention;

FIG. 6 is a circuit diagram illustrating an embodiment of an asynchronous control circuit according to the present invention;

FIG. 7 is a state transition diagram explaining an example of operating an asynchronous control circuit according to the present invention;

FIG. 8 is a state transition diagram explaining an example of operating an asynchronous control circuit according to the present invention;

FIG. 9 is a circuit diagram illustrating another embodiment of an asynchronous control circuit according to the present invention;

FIG. 10 is an entire block diagram illustrating an embodiment of an asynchronous pseudo 4 port SRAM according to the present invention;

FIG. 11 is a chip block diagram illustrating an embodiment of an asynchronous pseudo 4 port SRAM according to the present invention;

FIG. 12 is a pin layout diagram illustrating an embodiment of an asynchronous pseudo 4 port SRAM according to the present invention;

FIG. 13 is a rear view illustrating the BGA package shown in FIG. 12;

FIG. 14 is a chip block diagram illustrating another embodiment of an asynchronous pseudo 4 port SRAM according to the present invention;

FIG. 15 is a basic block diagram illustrating still another embodiment of an asynchronous pseudo multi-port memory according to the present invention;

FIG. 16 is a schematic block diagram illustrating an embodiment of a signal processing system using an asynchronous pseudo multi-port memory according to the present invention;

FIG. 17 is a block diagram illustrating an embodiment of a flip-plop circuit used for an asynchronous control circuit according to the present invention;

FIG. 18 is a block diagram illustrating an embodiment of a synchronous circuit according to the present invention;

FIG. 19 is a circuit diagram illustrating an embodiment of a synchronous circuit according to the present invention;

FIG. 20 is a waveform diagram illustrated to explain the operation of the synchronous circuit shown in FIG. 19 in a metastable state;

FIG. 21 is a block diagram illustrating another embodiment of an asynchronous multi-port memory using a synchronous circuit according to the present invention; and

FIG. 22 is a block diagram illustrating an embodiment of the present invention.

### DETAILED DESCRIPTION OF THE PREFERRED EMBODIMENTS

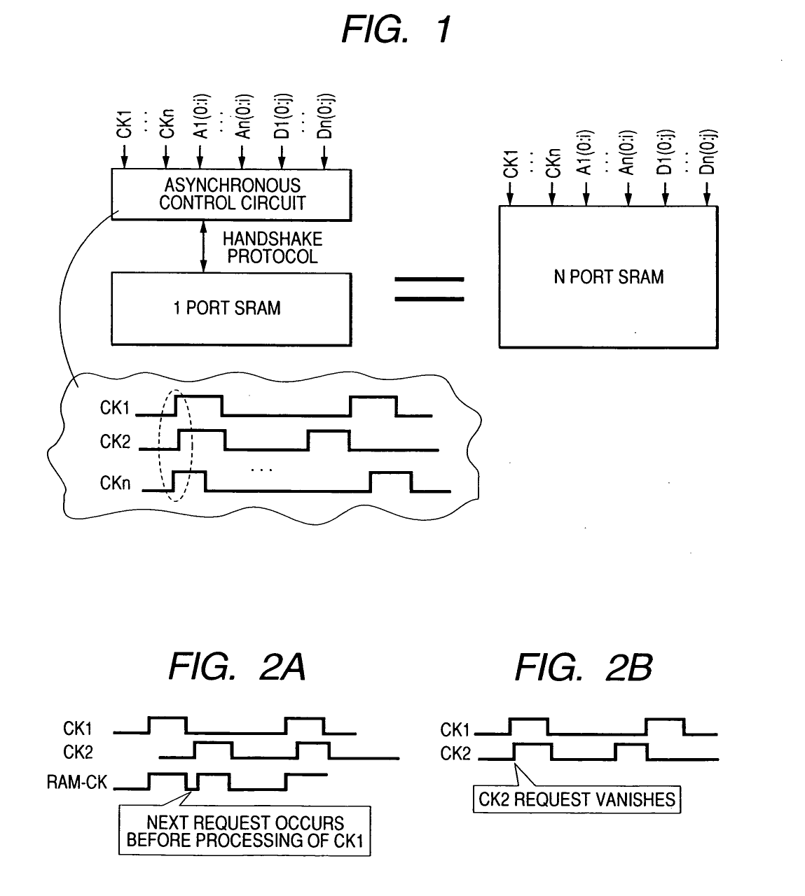

FIG. 1 is a concept diagram illustrating an example of an asynchronous type pseudo-multiport memory according to the present invention. The asynchronous type pseudo-multiport memory of this embodiment combines the asynchronous control circuit with a 1 port SRAM, achieving an equivalent N port SRAM. The above-mentioned asynchronous control circuit acknowledges the clock CK1-CKn, the address signal A1(0:i)-An(0:i) input according to each clock CK1-CKn, and the data signal D1(0:j)-Dn(0:j), and an equivalent N port SRAM is achieved by exchanging the signals with the 1 port SRAM according to a handshake protocol.

Here, the address signal (0:i) means i+1 bits from 0−i, and the data signal (0:j) means j+1 bits from 0−j. The above-mentioned clock CK1 or CKn is an access request signal when seen from the memory circuit side, for instance, a chip select signal CS and a chip enable signal CE are essentially regarded as the same as the above-mentioned clock CK in terms of circuit functionality.

In this embodiment, the clocks CK1-CKn are generated asynchronously. That is, they are timing signals of mutually different frequencies and phases, and the port number 1 or n is assumed to be a plural number of 3 or more; 3 or more clocks CK are input almost simultaneously or their phases are slightly different, and it is necessary to make it hazard-free to avoid malfunctions even for the variation of circuit devices within the asynchronous control circuit or deviations in signal propagation delay time, etc. Therefore, it is impossible to use the phase-comparison circuit as disclosed in the aforementioned patent document 2, so that it becomes necessary to develop a new asynchronous control circuit which satisfies the hazard-free requirement as mentioned above.

FIG. 2 is a timing chart to explain the clock competing relationship required by the asynchronous control circuit shown in FIG. 1. The example illustrated in FIG. 2A is the one necessary to suppress CK generation. When memory access is initiated by the previously generated clock CK1, and clock CK2 is input before completing the memory access according to the CK1, it is basically necessary to keep memory access of clock CK2 waiting until completing memory access by clock CK1. However, a problem arises that clock 1 and clock 2 are generated by a subtle timing difference caused by the existence of a circuit delay etc., and a double clock is generated at the RAM clock terminals RAM-CK. Because of such a double clock, memory access by the follower clock CK2 is neglected.

The example illustrated in FIG. 2B is the one necessary to avoid a critical race. When clocks CK1 and CK2 are input almost simultaneously, the memory access request of clock 2 should be executed after completing the memory access of previously input clock CK1, but the access request by clock CK2 which has to be executed afterwards varnishes because of a subtle timing difference between clocks CK1 and CK2.

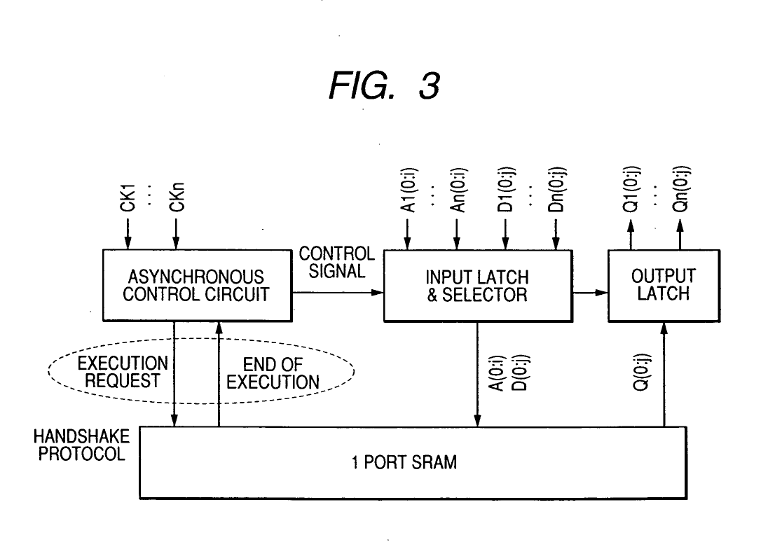

FIG. 3 is a basic block diagram illustrating an embodiment of an asynchronous type pseudo-multiport memory according to the present invention. The asynchronous type pseudo-multiport memory of this embodiment consists of an asynchronous control circuit, an input latch & selector, an output latch and 1 port SRAM. The above-mentioned input latch & selector may be included in the above-mentioned asynchronous control circuit. A configuration like this, in which the input latch & selector and output latch are included in the asynchronous control circuit, corresponds to the asynchronous control circuit illustrated in FIG. 1.

The above-mentioned asynchronous control circuit sends the execution request for memory access to the 1 port SRAM accepting clocks CK1-CKn, supplies a control signal for memory access corresponding to the above-mentioned execution request to the input latch & selector, and supplies one address signal A (0:i) and data D (0:j) selected by the selector to the 1 port SRAM. The 1 port SRAM selects the memory cell according to the above-mentioned address signal A (0:i) acknowledging the above-mentioned execution request, writes the data D (0:j) maintained in the above-mentioned input latch to the memory cell if it is a write operation, outputs the read data Q (0:j) of the selected memory cell to the above-mentioned output latch if it is a read operation, and communicates to the asynchronous control circuit the end of execution signal corresponding to completing the memory access in question. Thus, the asynchronous control circuit and the 1-port SRAM are coupled by a handshake protocol consisting of the execution request for memory access and the end of execution of the memory access corresponding thereto.

The asynchronous control circuit accepts the clock input which includes simultaneous input of more than two ports, and the input latch maintains the input signal, such as address and data, corresponding thereto. When the asynchronous control circuit accepts the aforementioned plurality of clock inputs, it selects one clock from them, and supplies the address, data A (0:i), and data D (0:j) maintained in the input latch to the above-mentioned 1 port SRAM by controlling the above-mentioned selector corresponding to the clock.

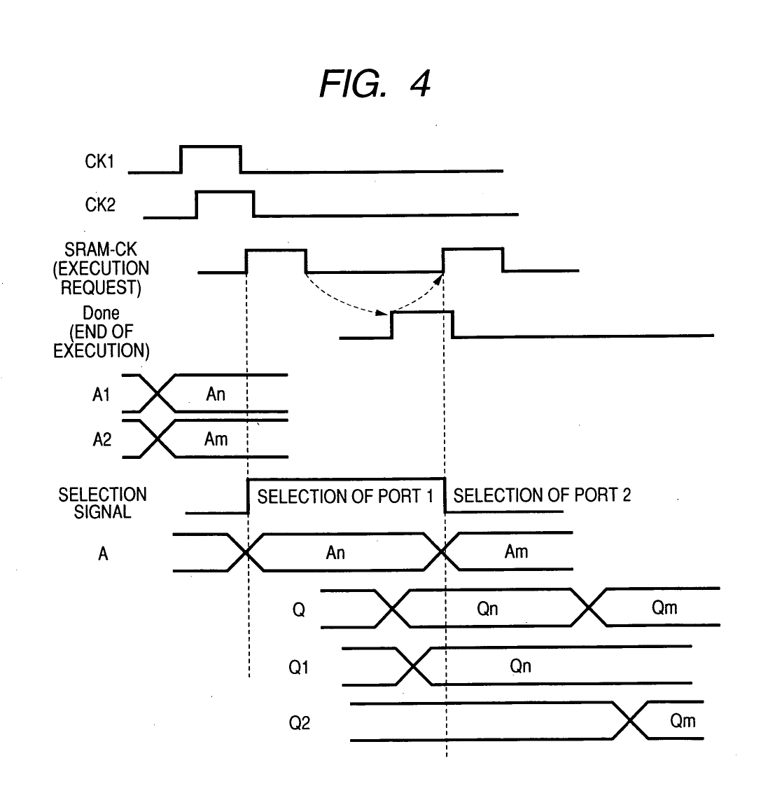

FIG. 4 is a simple timing chart to explain an operation of an asynchronous type pseudo-multiport memory according to the present invention. When the clocks CK1 and CK2 are input almost simultaneously, the address signal An is maintained in the input latch A1 corresponding to the clock CK1, and the address signal Am is maintained in the input latch A2 corresponding to the clock CK2.

Although it is not shown in this figure, during write operation, write data Dn are maintained in the input latch D1 corresponding to the clock CK1, and write data Dm are maintained in the input latch D2 corresponding to the clock CK2.

When the two clocks CK1 and CK2 are input almost simultaneously, not deciding accurately the phase difference between the clocks CK1 and CK2, but selecting the clock CK1 according to a predetermined priority-rank and supplying the clock as an execution request to the clock terminal SRAM-CK of the 1 port SRAM. Port 1 of the input latch corresponding to the above-mentioned clock CK1 is selected by the above-mentioned asynchronous control circuit; the address signal An maintained in the aforementioned input latch A1 is given in the address terminal A1 of the 1 port SRAM, thereby, the selection operation of the memory cell is performed. When a read operation of the above-mentioned address signal An is directed, the 1 port SRAM selects a memory cell corresponding to the above-mentioned address signal An and outputs the read signal Qn to the output latch. After completing the operation of outputting the data Qn to the output latch like this, the end of execution (Done) signal corresponding to the above-mentioned execution request is signaled back to the asynchronous control circuit.

Because of the existence of unexecuted clock CK2, the asynchronous control circuit supplies an execution request to the clock terminal SRAM-CK of the 1 port SRAM corresponding thereto, as well as selects the port 2 of the input latch corresponding to the clock CK2 and supplies the address signal Am maintained in the above-mentioned input latch A2 to the address terminal A of the 1-port SRAM. The selection operation of a memory cell is performed at the 1 port SRAM corresponding to the above-mentioned address signal Am. When a read operation of the above-mentioned address signal Am is directed, the 1 port SRAM selects a memory cell corresponding to the above-mentioned address signal Am and outputs the read signal Qm to the output latch. After completing the operation of outputting the data Qm to the output latch, the end of execution (Done) signal corresponding to the above-mentioned execution request is signaled back to the asynchronous control circuit.

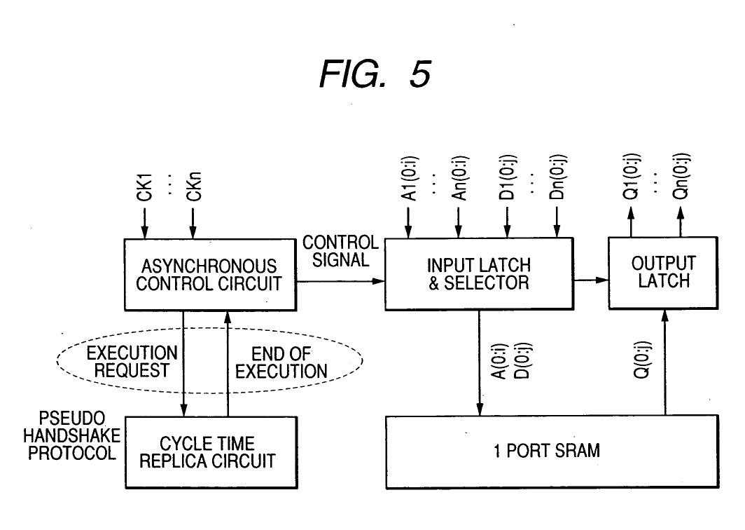

FIG. 5 is a basic block diagram illustrating an embodiment of an asynchronous type pseudo-multiport memory according to the present invention. This asynchronous type pseudo-multiport memory is a modified example of FIG. 3 and the cycle time replica circuit is newly installed. The cycle time replica circuit acknowledges the execution request for memory access to the 1 port SRAM, creates the end of execution signal after lapse of a delay time corresponding to the memory cycle, and signals it back to the above-mentioned asynchronous control circuit. Thus, the asynchronous control circuit performs a handshake protocol with the above-mentioned cycle replica circuit, therefore, it becomes a pseudo-handshaking protocol between the asynchronous control circuit and the 1 port SRAM.

By adopting a pseudo-handshaking protocol, it is not necessary for the 1 port SRAM to provide a function for creating the end of execution signal for the handshaking protocol as shown in aforementioned FIG. 3, and a conventional 1 port SRAM can be used. That is, in the case where the asynchronous control circuit and 1 port SRAM are used in a semiconductor integrated circuit, design data for a conventional 1 port SRAM can be used as is for the above-mentioned 1 port SRAM. Thereby, only the asynchronous control circuit has to be designed corresponding to the number of ports, and it is possible to shorten the time for developing an asynchronous type pseudo-multiport memory.

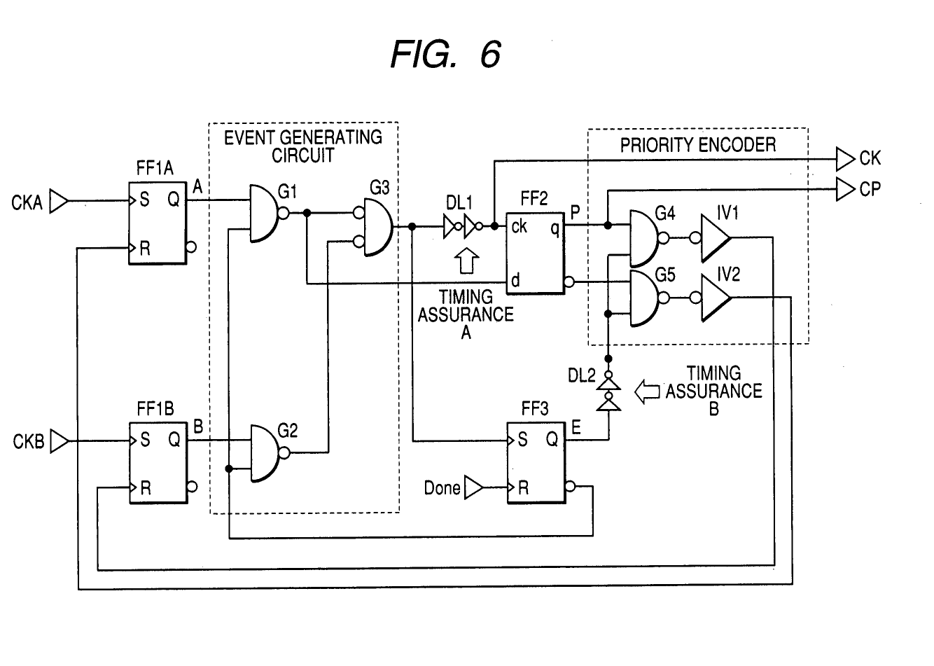

FIG. 6 is a circuit diagram illustrating an embodiment of an asynchronous control circuit according to the present invention. This embodiment relates to a dual port (two ports) hazard-free asynchronous control circuit and consists of three kinds of registers (flip-flop circuit) and two kinds of combinatorial logic circuits (event generating circuit, priority encoder). The register placed at the input part consists of SR (SET/RESET)-flip-flop circuits FF1A and FF1B, and is set by clocks CKA and CKB corresponding to the two ports A and B.

The output signals A and B of the above-mentioned flip-flop circuits FF1A and FF1B are transmitted to the combinatorial logic circuit constituting the event generating circuit. The above-mentioned event generating circuit forms an OR signal (A+B) from the output signals A and B of the above-mentioned flip-flop circuits FF1A and FF1B, and consists of NAND gate circuits G1, G2, and G3, although it is not limited thereto. This event generating circuit is transmitted to the register accepting an event and to the 1 port SRAM as the clock CK. The above-mentioned register consists of the SR (SET/RESET)-flip-flop circuit FF3.

Output signals A and B of flip-flop circuits FF1A and FF1B are respectively supplied to the inputs of one side of NAND gate circuits G1 and G2 consisting of the above-mentioned event generation circuit. The reversing output signal of flip-flop circuit FF3 which acknowledges the above-mentioned event is supplied to the inputs of the other side. That is, when the flip-flop circuit FF3 is set, the gate control signal which is supplied to the above-mentioned NAND gates G1 and G2 becomes a low level, and acknowledgement of the input is stopped.

In this embodiment, port A has a higher priority-rank versus port B. That is, the output signal of the above-mentioned event generating circuit is transmitted to the clock terminal ck of the flip-flop circuit FF2 constituting the register, and the output signal reversed by the gate circuit G1, which acknowledges the output signal A of the flip-flop circuit FF1A corresponding to the above-mentioned port A, is transmitted to the data terminal d. As a result, the SET/RESET of the flip-flop circuit FF1A through the gate circuit G1 is decided when an event is generated, and port A is selected if the flip-flop circuit FF1A is in the SET state. On the other hand, if the flip-flop circuit FF1A is in the RESET state, port B is selected. That is, port B is selected only when clock CKA is not input from port A.

The output signal P and the reversing signal of the above-mentioned flip-flop circuit FF2 are supplied to one of the inputs of the NAND gate circuits G4 and G5 consisting of the priority encoder. The output signal E of the flip-flop circuit FF3, which is a register accepting the above-mentioned event, is supplied to the other input of these gate circuits G4 and G5. The output signal P of the above-mentioned flip-flop circuit FF2 is transmitted as a port selection signal CP to an input latch not shown in the figure. For instance, in contrast with the control signal shown in FIG. 4, if the port selection signal CP is low-level, port A is selected, and if the port selection signal CP is high-level, port B is selected.

The output of the above-mentioned gate circuit G4 is reversed by the inverter circuit IV1, and input into the reset terminal R of the above-mentioned flip-flop circuit FF1B. The output signal of the above-mentioned gate circuit G5 is reversed by the inverter circuit IV2, and input into the reset terminal R of the above-mentioned flip-flop circuit FF1A. As mentioned above, when the output signal P of the flip-flop circuit FF2 is low-level, the end of acknowledgement is shown by selecting port A, and the flip-flop circuit FF1A corresponding thereto is reset by the output signal of the above-mentioned gate circuit G5, thereby, the acknowledgement following is enabled. On the other hand, when the output signal P of the flip-flop circuit FF2 is high-level, the end of acknowledgement is shown by selecting the port B, and the flip-flop circuit FF1B corresponding thereto is reset by the output signal of the above-mentioned gate circuit G4, thereby, the acceptance following is enabled.

In this embodiment, the output of the event generating circuit is transmitted as the timing assurance A to the clock terminal CK of the above-mentioned flip-flop circuit FF2 through the delay circuit DL1. This will be explained next, but it is something which assures timing in order to securely fetch the output signal of the gate circuit G1 by the event generating output. Moreover, as the timing assurance B, the output signal E of the above-mentioned flip-flop circuit FF3 is delayed by the delay circuit DL2, and transmitted as the gate control signal of the above-mentioned gate circuits G4 and G5. It will be explained next, but it is something which judges correctly the state of the flip-flop circuit FF2.

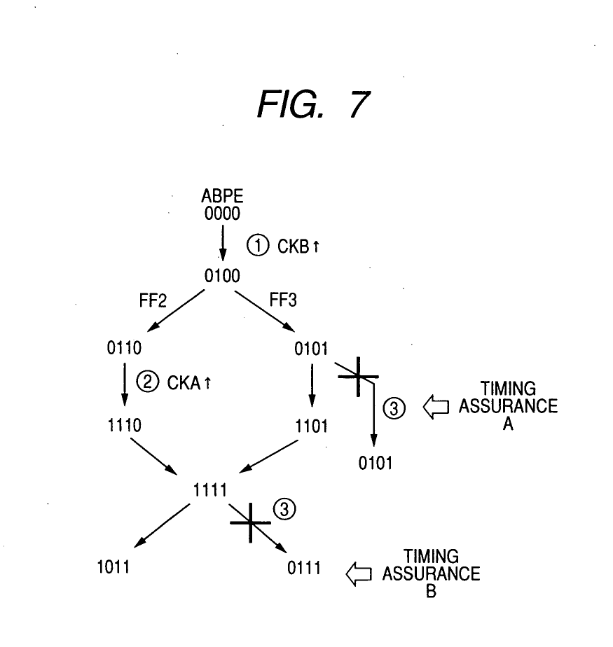

FIG. 7 is a state transition diagram explaining an example of operating an asynchronous control circuit of the present invention. In this figure, the four-bit information corresponding to ABPE corresponds to each register in the embodiment circuit illustrated in FIG. 6, that is, they correspond to the output signal A of the flip-flop circuit FF1A, the output signal B of FF1B, the output signal P of FF2, and the output signal E of FF3. At the initial state ABPE=0000, it changes to ABPE=0100 because of starting-up of the clock CKB corresponding to the access request to the B port. Because of this state 0100, the event generating circuit changes the states of the flip-flop circuits FF2 and FF3 corresponding to the access to the above-mentioned port.

This figure shows that the timing assurance A prevents a malfunction where a port A with the higher priority-rank is ignored and becomes 0101 when an access request to the port A with a higher priority-rank is generated and the clock CKA changes into high level during an access request to the above-mentioned B port. That is, the event signal, which is transmitted to the clock terminal CK of the flip-flop circuit FF2, is delayed by the delay circuit DL1 and the set state to the flip-flop circuit FF1A is reflected correctly.

Moreover, it also prevents a malfunction, in which the request to the port B is accepted by the flip-flop circuit FF2 and then, according to a request to the port A, port A awaiting execution is reset from the state ABPE=1111 to the state 0111 by the priority encoder. In other words, in order to reflect correctly the port accepted by the above-mentioned flip-flop circuit FF2 at the output of the priority encoder, the output signal E of the flip-flop circuit FF3 is delayed by the delay circuit DL2, and the timing assurance B is performed, thereby, the latest information accepted by the above-mentioned flip-flop circuit FF2 is correctly reflected in the output of the priority encoder The above-mentioned delay circuits DL1 and DL2 may be any which uses a delay circuit such as an inverter circuit, the gate circuits G3-G5 themselves placed in the transmission path, or one, where the signal delay of the above-mentioned signal transmission path is made to have a delay-time as mentioned above by a relationship with the signal delay which has a competitive nature, taking into consideration the length of connecting wiring and the parasitic capacitance of this wiring.

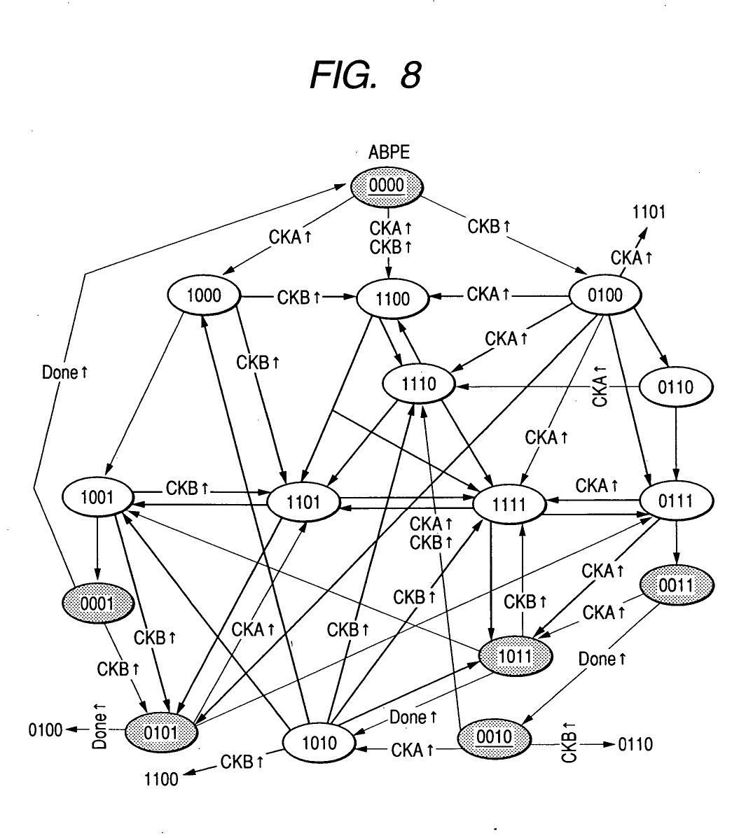

FIG. 8 is a state transition diagram explaining an example of operating an asynchronous control circuit of the present invention. This figure corresponds to the embodiment circuit illustrated in aforementioned FIG. 6, and the 4-bit information according to the ABPE corresponds to each register in FIG. 6 similar to the embodiment illustrated in FIG. 7, that is, to the output signal A of flip-flop circuit FF1A, the output signal B of FF1B, the output signal P of FF2, and the output signal E of FF3.

In this figure, open characters written on shaded backgrounds with underlined states indicate stable states. Open characters written on shaded backgrounds and not underlined states indicate quasi-stable states. This quasi-stable state means operation such as memory access etc. to the selected port, and transition is generated by completion signal Done of the memory access in question. Arrows with thick lines indicate transitions with lacing.

For instance, the initial state ABPE=0000 changes to 1000 when clock CKA is input to port A, to 1100 when clock CKA and CKB are simultaneously input to both ports A and B, and to 0100 when clock CKB is input to port B. The simplest operation is as follows. When clock CKA is input to port A and is selected, memory access is executed to the 1 port SRAM, and there is no access request from the other port B until the operation is complete, and it returns to states 1000->1001->0001->Done->0000 according to the thin line arrow. When the clock CKB is input to port B and is selected, memory access is executed to the 1 port SRAM, and there is no access request from the other port A until the operation is complete, and it becomes stable by states 0100->0110->0111->0011->Done->0010 according to the thin line arrow.

As mentioned above, there are two types of stable states, 0000 and 0010. While the output P of the flip-flop circuit FF2 becomes 1->0 by access from port A in the state where the flip-flop circuit FF2 is being set, when the output E of the flip-flop circuit FF3 becomes high-level, the flip-flop circuit FF1B corresponding to port B is allowed to reset by misjudging that port B is selected by the priority encoder as mentioned above. At this time, if there is an access request from port B, a malfunction is created where it is made invalid. However, because of the timing assurance B, such problem does not arise.

In this embodiment, even when clock CKA or CKB changes in the above-mentioned quasi-stable state and transition state, the state transition is generated as shown in the figure, the state finally becomes stable in either 0000 or 0010, and the port selection operation is executed according to a correctly decided priority-rank. In this embodiment, the state of the flip-flop circuit FF2 is finally judged by the output signal of the flip-flop circuit FF3, and because a port is selected with a higher priority-rank corresponding to this state, one port can be selected correctly without any relation to the number of ports.

The execution port is selected by the priority encoder according to the information fetched into the port register (FF2) as mentioned above, and the request acknowledgment register FF1 corresponding to the execution port is reset. Because the Done signal is asserted and the flip-flop circuit FF3 is reset when the execution of the 1 port SRAM core is complete, if an unexecuted request demand remains, the next request will be executed when the gates of event generating circuits G1 and G2 are opened.

The hazard-free asynchronous control circuit in this embodiment accepts the input of a plurality of clocks CK, selects one of the access requests, and outputs the execution address and data of the port corresponding to the execution request to the 1 port SRAM. When execution is complete, the SRAM core outputs the end of execution signal to the controlled circuit, and maintains the data in the output latch of the port corresponding thereto, and outputs it again with the address and data of the next execution wait. That is, the controlled circuit and the SRAM core are performing a sort of handshake protocol.

However, in a system in which an end of execution signal is output to the controlled circuit when the memory operation of such an SRAM core is complete, it is impossible to use a conventional SRAM core as-is because the SRAM core needs a mechanism which detects the enabling of an executable state and reports it to the controlled circuit. Therefore, as shown in the embodiment illustrated in the aforementioned FIG. 5, a handshake protocol is artificially achieved by adding a cycle time replica circuit of an SRAM core and performing asynchronous communication between controlled circuits. Because a multi-port SRAM can be realized with an area similar to that of a 1 port SRAM, a reduction in area becomes possible, and in the embodiment illustrated in FIG. 5, the design man-hours can be reduced because the 1 port SRAM can be reused as-is.

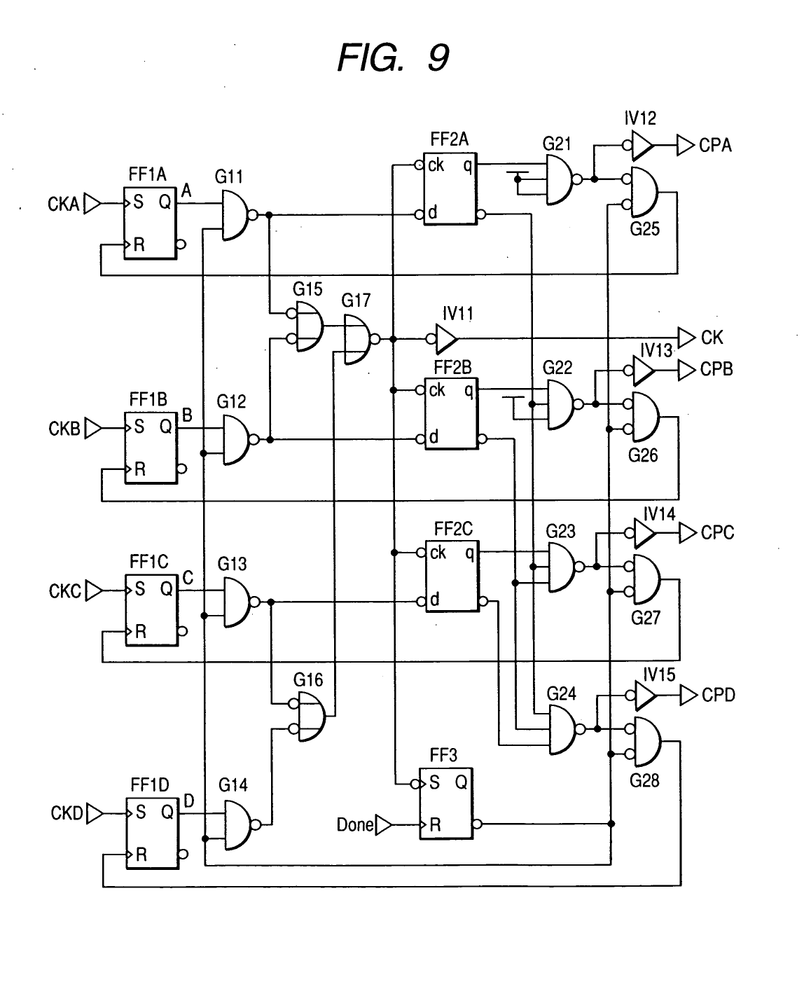

FIG. 9 is a circuit diagram illustrating another embodiment of an asynchronous control circuit according to the present invention. This embodiment relates to a 4 port hazard-free asynchronous control circuit, and the register placed at the input part consists of SR-flip-flop circuits FFA1, FF1B, FF1C, and FF1D mounted according to the four ports A, B, C, and D, and set to the clocks CKA, CKB, CKC, and CKD corresponding thereto.

The output signals A, B, C, and D of the above-mentioned flip-flop circuits FF1A, FF1B, FF1C, and FF1D are transmitted to the combinatorial logic circuit made up of gate circuits G11-G17 comprising the event generating circuit. The above-mentioned event generating circuit forms the reversed OR circuit (A+B+C+D) of the above-mentioned flip-flop circuits FF1A, FF1B, FF1C, and FF1D. This output signal of the event generating circuit is transmitted to the flip-flop circuit FF3, which is a register acknowledging the event, and to the flip-flop circuits FF2A, FF2B, and FF2C, which are port registers, while it is reversed by the output inverter circuit IV11 and transmitted to the 1 port SRAM as clock CK.

The output signals A, B, C, and D of the flip-flop circuits FF1A, FF1B, FF1C, and FF1D are respectively supplied to one input of NAND gate circuits G11-G14 constituting the above-mentioned event generating circuit, and the reversed output signal of the flip-flop circuit FF3 acknowledging the above-mentioned event is supplied to the another sides. That is, when the flip-flop circuit FF3 is set, the gate control signal supplied to the above-mentioned NAND gate circuits G11, G12, G13, and G14 becomes low-level, and the input acknowledgment is stopped.

In this embodiment, the priority-rank is set in the order of port A, port B, port C, and port D. That is, the output signal of the above-mentioned event generating circuit is transmitted to the clock terminal ck of the flip-flop circuits FF2A, FF2B, and FF2C constituting the port register. The output signal reversed by the gate circuit G11 accepting the output signal A of the flip-flop circuit FF1A corresponding to the above-mentioned port A is transmitted to the data terminal d of the above-mentioned flip-flop circuit FF2A. The output signal reversed by the gate circuit G12 accepting the output signal B of the flip-flop circuit FF1B corresponding to the above-mentioned port B is transmitted to the data terminal d of the above-mentioned flip-flop circuit FF2B. The output signal reversed by the gate circuit G13 accepting the output signal C of the flip-flop circuit FF1C corresponding to the above-mentioned port C is transmitted to the data terminal d of the above-mentioned flip-flop circuit FF2C.

When an event is generated, flip-flop circuits FF1A-FF1C are judged SET/RESET through the gate circuits G11-G13, port A is selected if the flip-flop circuit FF1A is in the SET state, port B is selected if the above-mentioned flip-flop circuit FF1A is in the RESET state and flip-flop circuit FF1B is in the SET state, port C is selected if the above-mentioned flip-flop circuits FF1A and FF1B are in the RESET state and the flip-flop circuit FF1C is in the SET state, port D is selected if the above-mentioned flip-flop circuits FF1A, FF1B, and FF1C are in the RESET state.

That is, even when event is generated, the above-mentioned three flip-flop circuits FF1A, FF1B, and FF1C being in the RESET state means that the flip-flop circuit FF1D is judged to be in the SET state.

In order to select a port according to the above-mentioned priority-rank, the output signal q of the above-mentioned flip-flop circuits FF2A-FF2C and the reversed signal thereof are transmitted to the gate circuits G21-G24 constituting the priority encoder. One output signal from these gate circuits G21-G24 is made a low-level selection state according to the priority-rank. The output signals of these gate circuits G21-G24 are transmitted to the reset terminals of the above-mentioned flip-flop circuits FF1A-FF1D through and corresponding to each of the gate circuits G25-G28 in which the gates are controlled by the output signal of the flip-flop circuit FF3 being the above-mentioned event acknowledgment register. Thereby, of the flip-flop circuits FF1A-FF1D in the input section, the one corresponding to the port is reset, which is selected like the embodiment shown in the aforementioned FIG. 6.

The above-mentioned gate circuit G21 or G24 is output through the inverter circuits IV12-IV15 used for output. That is, one output signal out of the four gate circuits G21-G24 corresponding to the above-mentioned priority-rank becomes low-level, is reversed by the above-mentioned inverter circuits IV12-IV15 corresponding thereto, and is output. Thereby, one of the port selection signals CPA-CPD, which is made high-level, selects a selector of the input latch which is not illustrated. In this embodiment, the delay circuits for timing assurance A and timing assurance B shown in the aforementioned FIG. 6 are omitted, but it may be installed according to the operation conditions of the circuit. In this case, timing assurance A may be achieved by using the signal delay at the gate circuits G15, G16, and G17 forming the OR output of the event generating circuit.

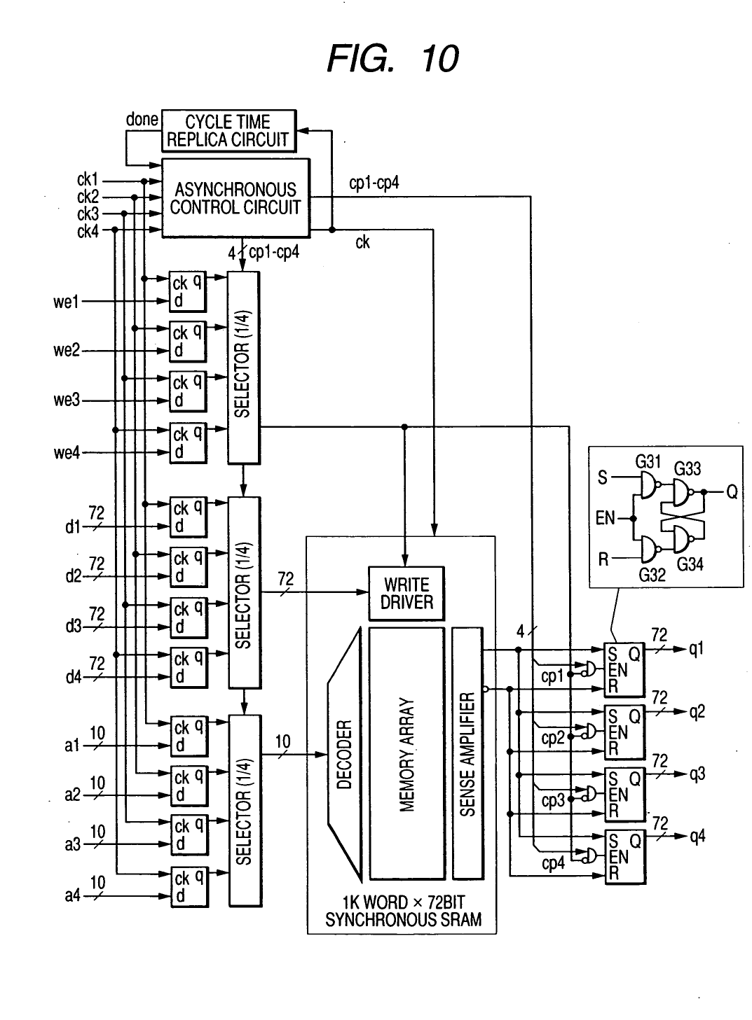

FIG. 10 is an entire block diagram illustrating an embodiment of an asynchronous pseudo 4 port SRAM according to the present invention. Each circuit block of this figure is formed by a well-known manufacturing technique of a semiconductor integrated circuit on a semiconductor substrate such as single-crystalline silicon. The asynchronous pseudo 4 port SRAM consists of a combination of a 1 port SRAM and an asynchronous control circuit. Moreover, as the input circuit, each input latch and selector for controlling the signal input (we1-we4), for writing data (d1-d4), and for addresses (a1-a4), are respectively installed corresponding to the number of ports, and, as the output circuit, output latches for data output (q1-q4) are installed corresponding to the number of ports.

As illustrated in the close-up example in this figure, the output latch consists of a SET/RESET flip-flop circuit in which an enable terminal E consisting of NAND gate circuits G31-G34 is installed. The logic signal of the selected control signal we and the port selection signals cp1-cp4 are transmitted to the enable terminal E, and, during a read operation of the selected port, the output latch corresponding thereto is made effective and the output signal of the sense amplifier is fetched.

Although the 1 port SRAM is not specified, it consists of a 1K word×72-bit synchronization SRAM. Therefore, 72 memory cells of the memory array are selected by the decoder; the stored information of the selected memory cells is amplified by the sense amplifier, and output in 72-bit units to the output latch corresponding to the selected port. The write driver accepts the above-mentioned write data, and the data corresponding to the selected port is written in the memory array.

The asynchronous control circuit of the present invention receives the clocks ck1-ck4 asynchronously input from the four ports, and, when the clocks are simultaneously supplied from a plurality of ports, it selects one port according to the priority-rank and supplies the clock ck, control signal we, and address a to the synchronous SRAM. If it is a write operation, the write data d are also fetched. If it is a read operation, the read signal from the selected memory cell is output by the above-mentioned address a as the data output q. The asynchronous control circuit receives the end of execution signal, done, of the synchronous SRAM, which is formed by the cycle time replica circuit corresponding to the above-mentioned synchronous SRAM, and executes continuously the access by the unexecuted port.

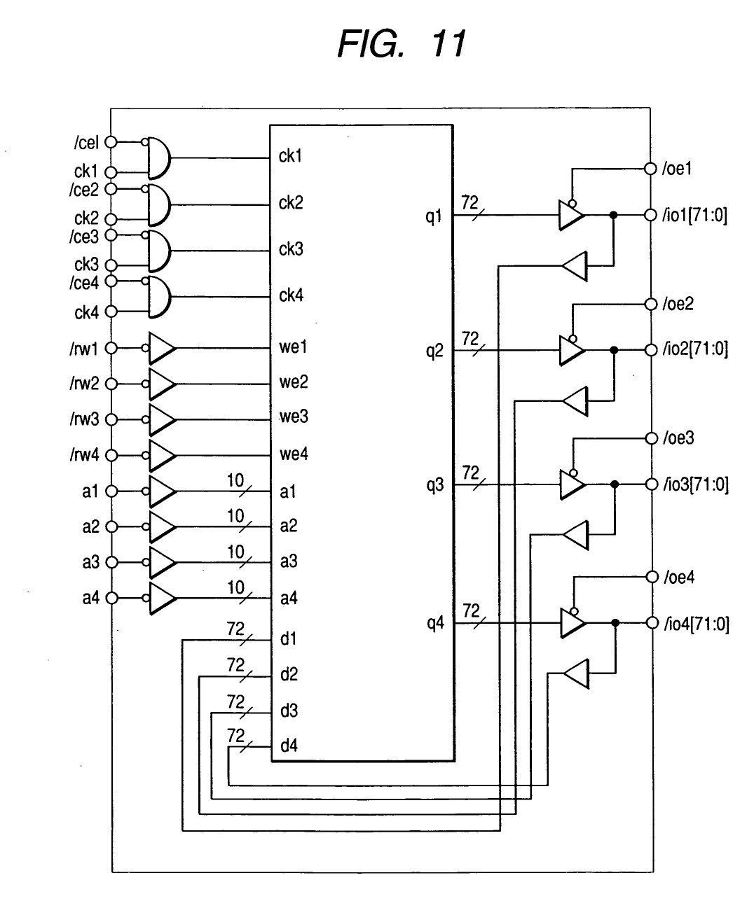

FIG. 11 is a chip block diagram illustrating an embodiment of an asynchronous pseudo 4 port SRAM according to the present invention. In this embodiment, data input and output are carried out using the common data terminals /io1-/io4.

The output enable terminals /oe1-/oe4 are installed and they are made the operation control signal of the output buffer having a three-state output function. Operation of the output buffer circuit is made effective, and the data is output from the corresponding outer terminal /io1-/io4.

The internal circuit shown as the black box consists of the aforementioned asynchronous control circuit, cycle time replica circuit, input latch, selector and 1 port synchronous SRAM, and output latch. The write data input from the outer terminals /io1-/io4 are input as the write data input d1-d4 into the input latch installed in the above-mentioned black box. The address signals a1-a4 are input into the corresponding input latch through the address input buffer. Read/write control signals /rw1-/rw4 are input into the corresponding input latch through the control input buffer. The clock enable terminal /ce1 or /ce4 is installed corresponding to the clock terminal ck1 or ck4; these AND operations are taken by the gate circuits which double as the input buffers, and the clock signals ck1-ck4 transmitted to the asynchronous control circuit in the black box are generated.

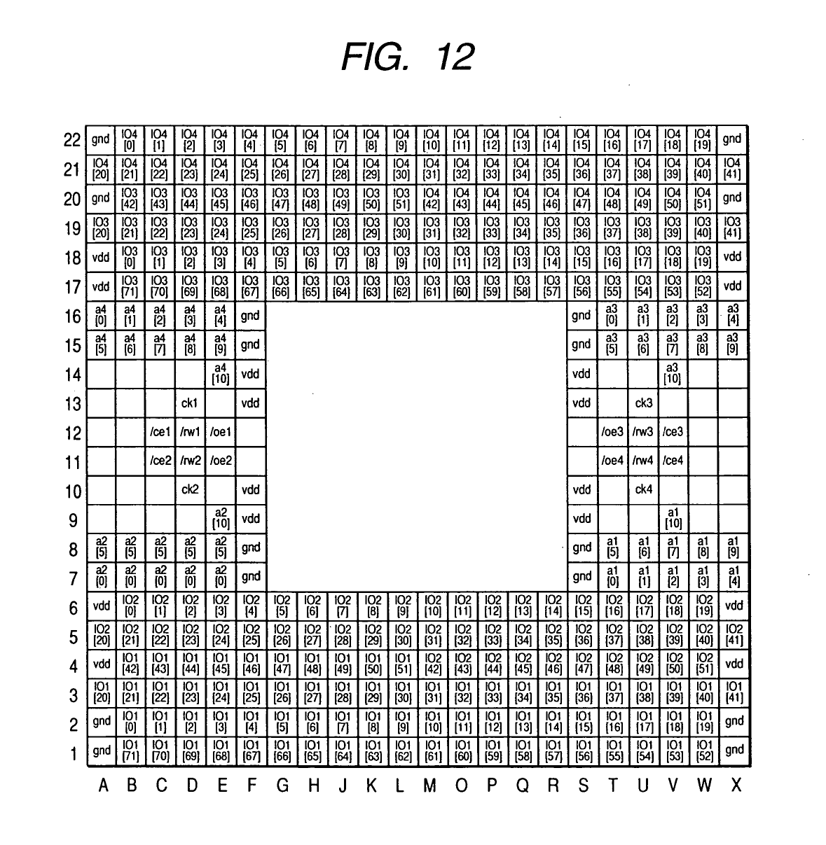

FIG. 12 is a pin layout diagram illustrating an embodiment of an asynchronous pseudo 4 port SRAM according to the present invention. The asynchronous pseudo 4 port SRAM in this embodiment is installed in a BGA (Ball Grid Array) package.

Except for the center of the part in which the chips are installed as shown in FIG. 11, the outer terminals consisting of solder balls are arranged in the shape of a grid. The address terminals a1-a4 corresponding to the above-mentioned 4 ports, data terminals IO1-IO4, clock enable terminals /ce1-ce4, output enable terminals /oe1-/oe4, read/write control terminals /rw1-/rw4, clock terminals ck1-ck4, and a plurality of distributed installed electrical source terminals vdd and ground terminals gnd are allocated as shown in this figure.

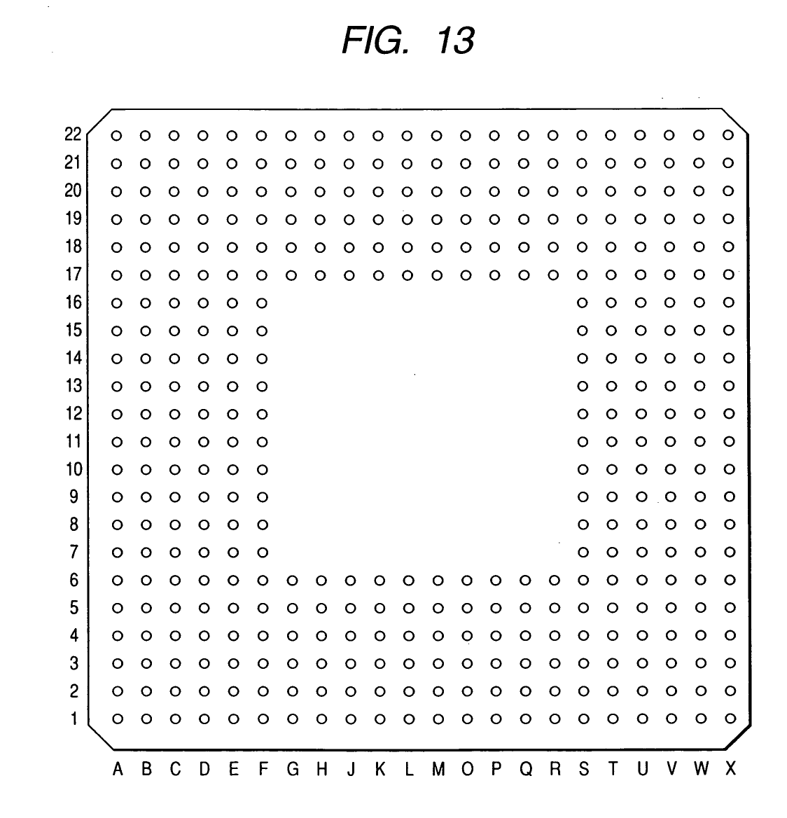

FIG. 13 is a rear view illustrating the BGA package shown in FIG. 12. The picture shows the external terminal consisting of solder balls, etc. arranged like a grid corresponding to the pin configuration shown in FIG. 12. In this embodiment, solder balls are placed in the empty terminals in FIG. 12.

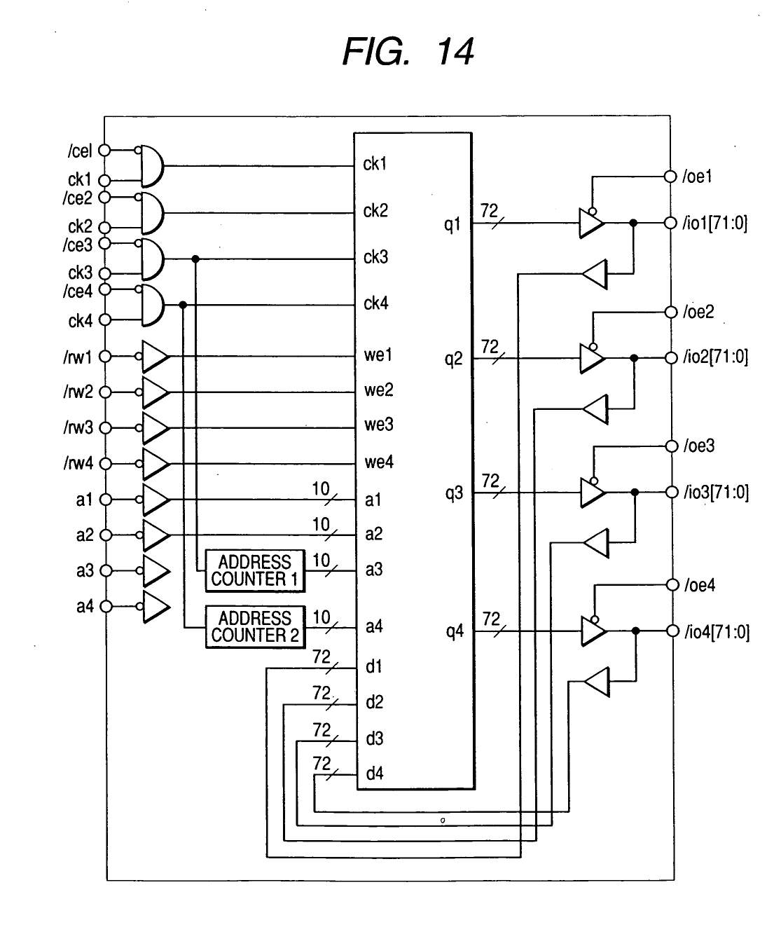

FIG. 14 is a chip block diagram illustrating another embodiment of an asynchronous pseudo 4 port SRAM according to the present invention. In this embodiment, two ports out of four ports are used for random I/O and the other two ports are used for serial I/O. Two ports corresponding to the clocks ck1 and ck2 are used for the random I/O. On the other hand, two ports corresponding to the clocks ck3 and ck4 are used for the serial I/O. The address counters 1 and 2 are installed for the serial I/O; address stepping operation of the above-mentioned address counters 1 and 2 is executed by the clocks ck3 and ck4, and the address signals generated by the address counters 1 and 2 in question are fetched by the input latch of the ports corresponding to addresses a3 and a4.

The parts except for the above-mentioned ports 1 and 2 and the part generating the address signals a3 and a4 with the above-mentioned address counter is made to have the same configuration as the aforementioned FIG. 11. The above-mentioned ports 3 and 4 make the clock enable /ce3 and /ce4 effective, and, +1 is added in each address to execute a write or read only by inputting the clocks ck3 and ck4. As a result, because the selection operation of the memory cell is executed by a continuous address, it makes serial-input and serial-output of data possible.

Three ports 1-3 may be used for the random I/O and the remaining port 4 may be used for the serial I/O. Data can be rewritten at random to the memory array using the three ports, and it can be output from the one port in order. For instance, images and characters can be updated by using the above-mentioned three ports, and display data can be output regularly from the above-mentioned one serial port according to the operation of the display device. In this case, it only has to assume the priority-rank of the above-mentioned serial port to be lower rank when the display operation is slower than the update of images and characters, and, when the priority is put on the display operation, it only has to assume the priority-rank of the above-mentioned serial port to be the highest priority-rank.

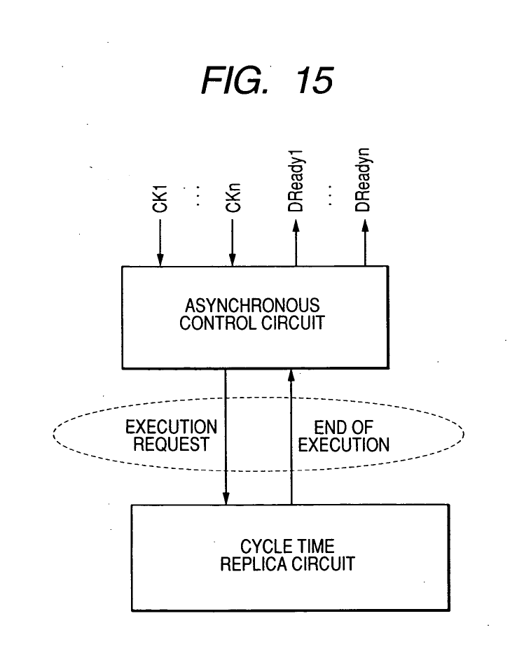

FIG. 15 is a basic block diagram illustrating still another embodiment of an asynchronous pseudo multi-port memory according to the present invention. The asynchronous pseudo multi-port memory in this embodiment is a modified example of the embodiment illustrated in FIG. 5 and the control signals DReady1-DReadyn, which realize an asynchronous communication interface from an asynchronous control circuit. These control signals DReady1-DReadyn are the end of execution signal, and they are the ones to enable the asynchronous communication of the user logic with the macro cell.

The above-mentioned control signals DReady1-DReadyn may be a microprocessor accessing the asynchronous pseudo multi-port memory and the above-mentioned user logic etc. may make the next access possible to be permitted by, for instance, receiving the above-mentioned signal DReady1. In the case where the chance of memory access is equally allocated to 1 or n ports, the above-mentioned signals DReady1-DReadyn are returned to the microprocessor and the user logic from the asynchronous control circuit after waiting for the end of the non-executed memory access with the lowest priority-rank. Or, it may be the one which lets the above-mentioned microprocessor and user logic know that there is effective data for the above-mentioned DReady1 in the output latch. The configuration to allocate the chance of memory access equally to the above-mentioned n port may be achieved by executing the memory access request cyclically n times within the memory cycle in the microprocessor and user logic, etc. which executes memory access.

FIG. 16 is a schematic block diagram illustrating an embodiment of a signal processing system using an asynchronous pseudo multi-port memory according to the present invention. In the configuration of FIG. 16A, the aforementioned asynchronous control circuit is included in the 2 port SRAM. The microprocessor CPU1 executes memory access occupying one of the two ports. On the other hand, the remaining one port is for executing memory access asynchronously between the two microprocessors CP2 and CP3 through the asynchronous control circuit.

According to this configuration, an equivalent 3 port SRAM can be achieved using the 2 port SRAM. The asynchronous control circuit of the present invention is not limited by the combination with a 1 port SRAM, but it is one where an asynchronous control circuit is installed in an N port SRAM including a 1 port SRAM, and an asynchronous SRAM with M ports (M>N) can be achieved. In this signal processing system, it may be possible to transfer data between CPU1-CPU2 having mutually different system clocks.

FIG. 16B shows a combination of an asynchronous control circuit and an operator, and the operator can be shared by the two microprocessors CP1 and CP2. For instance, as an operator, it has comparatively little frequency of use like a divider, and is useful for one having a large number of cycles until an operator result is obtained. Because CPU1 or CPU2 sends the multiply command to the shared operator asynchronously to each other and can fetch the operator result when it is obtained while executing other signal processing, it becomes possible to achieve a simple system configuration and efficient signal processing. Anything which has signal input and corresponding signal output, other than a memory circuit, may be acceptable for a circuit controlled by an asynchronous control circuit like this.

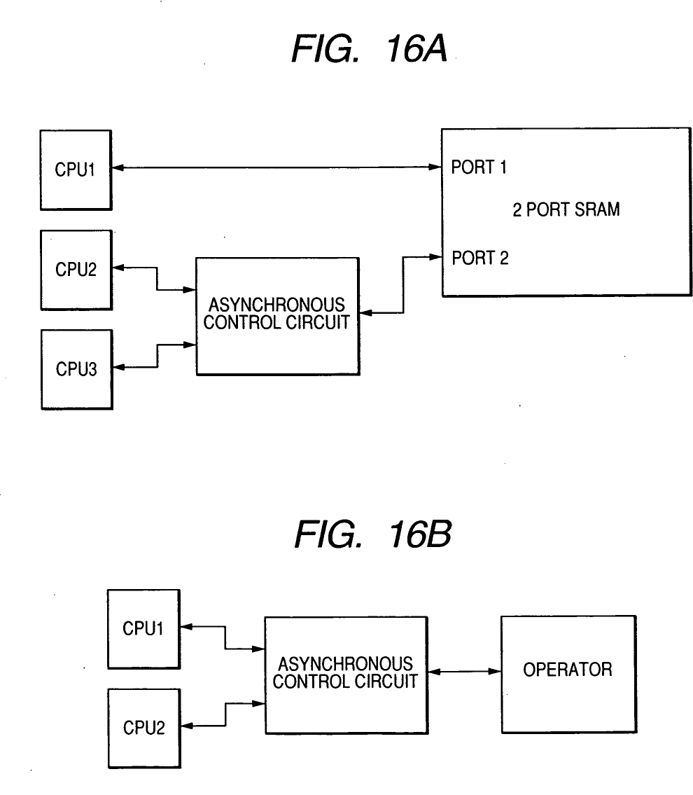

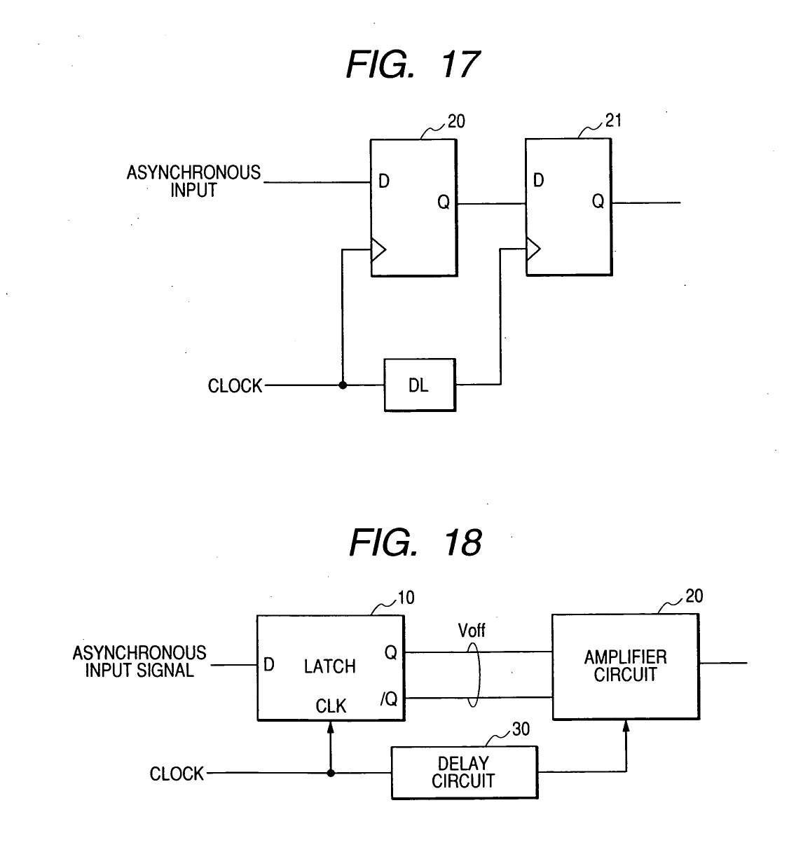

FIG. 17 is a block diagram illustrating an embodiment of a flip-plop circuit used for an asynchronous control circuit according to the present invention.

In the aforementioned FIGS. 6 and 9, when a typical flip-plop circuit is used for the flip-plop circuits FF2 and FF2A-FF2C, a metastable state (quasi-stable state) is created. That is, in a circuit which has two stable states while waiting for a feedback loop like a flip-flop circuit, it is known that it becomes stable with a certain possibility at an intermediate level other than the two states, a so-called metastable state or quasi-stable state. This metastable state or quasi-stable state is a temporary one which, in the end, because of regular noise and power source variations, etc., becomes stable in either of the above-mentioned two states. However, because the above-mentioned metastable state outputs an intermediate level, a malfunction is created in the circuit shown in the aforementioned FIG. 6 in which the output signals of the flip-flop circuits FF2 are judged as the same high-level or low-level input signals, which should have a high-level/low-level complementary relationship because of the relationship between the logic threshold voltages of the gate circuits G4 and G5. It is similar to the gate circuits G21-G24 shown in FIG. 9.

Then, in this embodiment, a synchronous circuit is used as the flip-flop circuits FF2 and FF2A-FF2C shown in the aforementioned FIGS. 6 and 9 to avoid the metastable state. That is, using the flip-flop circuits 20 and 21, the asynchronous signal from the event generating circuit of the aforementioned FIG. 6 is supplied to the data terminal D of the previous flip-flop circuit 20, and then the clock signal passed though the delay circuit DL is supplied to the clock terminal. Then, the output signal Q of the previous flip-flop circuit 20 is input to the data terminal D of the flip-flop circuit 21, and the clock signal delayed by the delay circuit DL is supplied to the clock terminal. In the two-stage synchronous circuit, as previously described the characteristic is used whereby the metastable state becomes stable in either of the above-mentioned two states due to regular noise and power supply variations. Therefore, the delay circuit DL is set to a delayed time only required to stabilize in either of the two above-mentioned states. Using such two-stage synchronous circuits 20 and 21 can prevent malfunctions in the aforementioned pseudo multi-port memory.

FIG. 18 is a block diagram illustrating an embodiment of a synchronous circuit according to the present invention. The synchronous circuit shown in FIG. 17 uses a characteristic where a metastable state becomes stable in either of the two above-mentioned states due to regular noise and power supply variations, etc. Therefore, it is necessary to operate the flip-flop circuit 21 on the subsequent stage with a comparatively long delay time. Therefore, in the case where it is applied to a multi-port memory, the memory access time becomes longer because fetching the asynchronous signal is delayed by the above-mentioned delay time. Then, this embodiment is one designed to fetch the asynchronous signal at high speed.

The asynchronous input signal is input to data terminal D of latch (or, flip-flop) circuit 10 as the first step. The clock is supplied to clock terminal CLK. In such a latch circuit 10, the metastable state is generated by a certain probability as mentioned above. However, this latch circuit 10 is set to intentionally have a constant offset voltage Voff against the output signal from the non-reversing output Q and reversing output /Q in a metastable state. Additionally, a pair of output terminals Q and /Q of the above-mentioned latch circuit 10 are supplied to a pair of input terminals of the amplifier circuit and are amplified. Although it is not specified, this amplifier operation is initiated by the timing signal where the above-mentioned clock is delayed by the delay circuit 30.

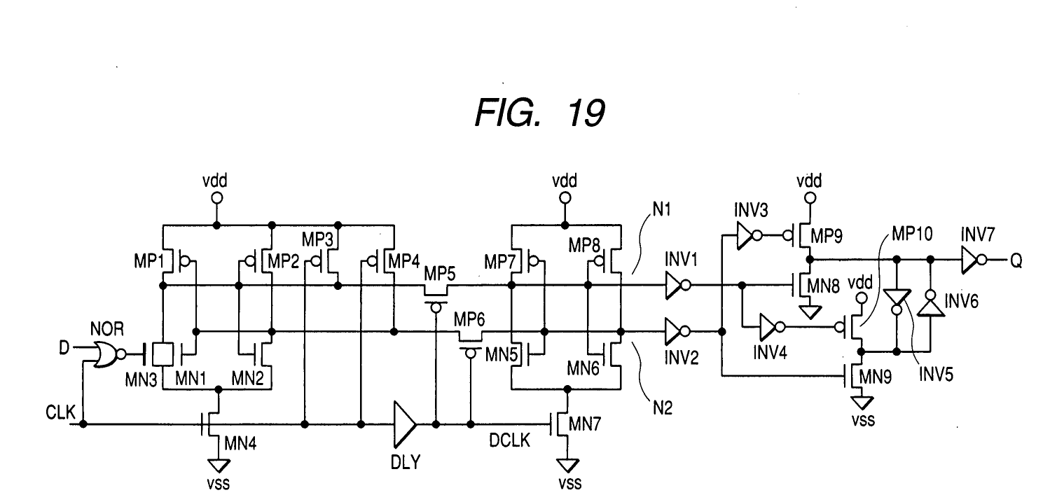

FIG. 19 is a circuit diagram illustrating an embodiment of a synchronous circuit according to the present invention. The synchronous circuit described in this embodiment consists of a two-stage latch circuit and an output latch circuit. The latch circuit in the first stage is set to be a differential output and the latch circuit in the second stage is set to be a differential input. A differential output of the latch circuit in the first stage and a differential input of the latch circuit in the second stage are connected to each other by the P-channel MOSFETs MP5 and MP6 controlled by the same timing as the latch circuit in the second stage. Moreover, the latch circuit in the second stage is connected to the output latch circuit to maintain the output data.

Two CMOS inverter circuits with cross-connected input and output are used for the latch circuit on the first stage. One CMOS inverter circuit consists of an N-channel MOSFET MN1 and P-channel MOSFET MP1. Another CMOS inverter circuit consists of an N-channel MOSFET MN2 and P-channel MOSFET MP2. The power supply voltage vdd is supplied for the sources of the above-mentioned P-channel MOSFETs MP1 and MP2. N-channel MOSFET MN4 is installed between the sources of the N-channel MOSFETs MN1 and MN2 and the ground voltage of the circuit. Then, P-channel MOSFETs MP3 and MP4 are installed for precharge or pull-up between the power supply voltage vdd and a pair of I/O nodes cross-connecting the above-mentioned input and output. N-channel MOSFET MN3, which acknowledges the input signal, is connected in a parallel configuration with the N-channel MOSFET MN1 constituting one of the above-mentioned CMOS inverter circuits. Asynchronous input signal D and clock signal CLK are supplied to the gate of this MOSFET MN3 through NOR gate circuit NOR. And clock signal CLK is supplied to the gates of N-channel MOSFET MN4 and above-mentioned P-channel MOSFETs MP3 and MP4.

When the clock signal CLK is a low-level, because of the P-channel MOSFETs MP3 and MP4, the cross-connected input and output of the two CMOS inverter circuits having the above-mentioned latch configuration are charged-up or pulled-up to a high-level such as the power supply voltage vdd. In this embodiment, in order to give an offset voltage Voff to a pair of output signals in the metastable state, the N-channel MOSFET MN1 of one of the above-mentioned CMOS inverter circuits is made in a smaller size (small conductance), about 1/10 that of the N-channel MOSFET NM2 of the other CMOS inverter circuit.

When the asynchronous input signal D is a high-level, the output signal of NOR gate circuit NOR is a low-level, and N-channel MOSFET MN3 is in OFF state.

When the clock signal CLK changes from low-level to high-level, the above-mentioned P-channel MOSFETs MP3 and MP4 become in OFF state and the above-mentioned N-channel MOSFET MM4 becomes in ON state. Because the change of drain voltage of the N-channel MOSFET MN2 is faster than that of the N-channel MOSFET MN1, the N-channel MOSFET MN1 becomes in OFF state and the N-channel MOSFET MN2 becomes in ON state, thereby, the data corresponding to the asynchronous input signal of the above-mentioned low-level can be stored.

When the asynchronous input signal D is a low-level, the output signal of NOR gate circuit NOR is a low-level, and N-channel MOSFET MN3 is in ON state. Thus, when the clock signal CLK changes from low-level to high-level, the above-mentioned P-channel MOSFETs MP3 and MP4 become in OFF state and the above-mentioned N-channel MOSFET MM4 becomes in On state. Thereby, corresponding to the ON state of the above-mentioned N-channel MOSFET MN3, the N-channel MOSFET MN2 becomes in OFF state and the N-channel MOSFET MN1 becomes in ON state, so that the data opposite to the above-mentioned can be stored. In this storage state, the N-channel MOSFET MN3 is made OFF state caused by the low-level of the output signal of the above-mentioned NOR gate circuit NOR, and the data are stored corresponding to the ON/OFF of the above-mentioned N-channel MOSFETs MN1 and MN2.

When asynchronous signal D is input almost simultaneously into the clock signal CLK, there is a possibility that the current flowing to N-channel MOSFET MN1 and MN2 is balanced and becomes metastable state (quasi-stable state) for a while. It is expected that such a metastable state (quasi-stable state) is generated at a certain constant frequency when the frequency of the clock CLK is different from the frequency of the circuit generating the asynchronous input signal. In this embodiment, in the case where the above-mentioned quasi-stable state is generated, the gate voltage of the N-channel MOSFET MN1 must become higher than the gate voltage of the N-channel MOSFET MN2 in order to flow the same current into both MOSFETs, because the dimension of the N-channel MOSFET MN1 is smaller than that of the N-channel MOSFET MN2. This means that a constant offset voltage Voff exists in the output signal consisting of non-reversed output signal (Q) and reversed output signal (/Q) of the latch circuit. Thus, in the latch circuit of the first stage, even if a metastable state is generated, a potential difference corresponding to the size ratio of N-channel MOSFETs MN1 and MN2 can be generated between the output signals of the non-reversed output (positive) signal and reversed output (negative) signal.

The latch circuit of the second stage is an amplifier circuit which senses the above-mentioned offset voltage Voff, and a latch circuit is used to make it high sensitivity and low electric power consumption, although it is not specified. This latch circuit consists of cross-connecting the inputs and outputs of one CMOS inverter circuit, which consists of N-channel MOSFET MN5 and P-channel MOSFET MP7, with another CMOS inverter circuit, which consists of N-channel MOSFET MN6 and P-channel MOSFET MP8. The power supply voltage vdd is supplied to the sources of the above-mentioned P-channel MOSFETs MP7 and MP8. The N-channel MOSFET MN7 is installed between the sources of the N-channel MOSFETs MN5 and MN6 and the ground voltage of the circuit. A pair of input terminals of the above-mentioned latch circuit is connected to a pair of output terminals of the first stage latch circuit and P-channel MOSFETs MP5 and MP6. Then, the signal DCLK, which is delayed by the delay circuit DLY, is supplied to the above-mentioned P-channel MOSFETs MP5 and MP6 and N-channel MOSFET MN7 gate.

Because such latch circuit is used, the clock signal CLK can be operated by the signal DCLK delayed by the delay circuit DLY to fetch the above-mentioned offset voltage Voff.

That is, when the signal DCLK changes from low-level to high-level, the P-channel MOSFETs MP5 and MP6 become off and the aforementioned offset voltage Voff is fetched in the input of the latch circuit of the second stage, even if a metastable state is generated. Because the above-mentioned signal DCLK is high-level, the N-channel MOSFET MN7 becomes in On state. The N-channel MOSFETs MN5 and MN6 of the latch circuit of the second stage are made to be the same dimension, and the P-channel MOSFETs MP7 and MP8 are also made the same dimension. That is, the input offset is designed to be small corresponding to process variations.

This latch circuit of the second stage is operated, for instance, as a dynamic type memory sense amplifier and to amplify the potential difference between nodes N1 and N2 as well.

In a practical circuit, there is an offset distribution in the input voltage of this latch circuit of the second stage because of the aforementioned process variation within the chips. However, the offset voltage Voff in the latch circuit of the first stage, which is an output potential difference when the metastable state is generated, is designed to be larger than the variation in input offset voltage of the latch circuit of the second stage. Therefore, even if a metastable state (quasi-stable state) is generated in the latch circuit of the first stage, the above-mentioned offset voltage Voff is amplified by the latch circuit of the second stage and can be made to settle at one of the logic levels corresponding to a stable output state. The delay time of the above-mentioned delay circuit DLY may be quite a short, period, enough to fetch into the second latch circuit the offset voltage Voff of the metastable state in the latch circuit of the first stage. In other words, since there is no need to wait until the metastable state is solved as shown in the synchronous circuit in the aforementioned FIG. 17, it is possible to do away with the great increase in delay time like in the synchronous circuit in the aforementioned FIG. 17.

The above-mentioned latch circuits of the first and second stages have operation/non-operation (precharge or reset period) corresponding to clock CLK. Therefore, in the non-operation period, the output latch is installed in order to keep the asynchronous signal (including metastable state) which is fetched just before.

In the output latch, the signals of a pair of nodes N1 and N2 in the above-mentioned latch circuit of the second stage are input into the inverter circuits INV1 and INV2. The output signals of these inverter circuits INV1 and INV2 are transmitted to the gates of N-channel MOSFETs MN8 and MN9 on one side. The output signals of above-mentioned inverter circuits INV1 and INV2 are cross-input into the inverter circuits INV4 and INV3 on the other side, and the reversed-output signals are transmitted to the gates of the P-channel MOSFETs MP9 and MP10. The above-mentioned N-channel MOSFETs MN8 and MP9 and the above-mentioned N-channel MOSFETs MN9 and MP10 are individually connected in series between the power supply voltage vdd and the circuit ground voltage vss, and comprise the tri-state output circuit. The drain output signal connected in common with the above-mentioned MOSFETs MN8 and MP9 and the drain output signal connected in common with the above-mentioned MOSFETs MN9 and MP10 are transmitted to the latch circuit comprising the cross-connected input and output of the inverter circuits INV5 and INV6. One output signal of this latch circuit is transmitted to the output terminal Q which obtains a synchronous signal through the inverter circuit INV7.

In the precharge (reset) period in which the clock signal CLK is low-level, both aforementioned nodes N1 and N2 are precharged to high-level. Therefore, because the output signals of both inverter circuits INV1 and INV2 are made low-level, the N-channel MOSFETs MN8 and MN9 constituting the above-mentioned tri-state output circuit are made off state. Moreover, because the output signals of both inverter circuits INV3 and INV4 are made high-level, the P-channel MOSFETs MP9 and MP10 constituting the above-mentioned tri-state output circuit are made off state. Therefore, because these two tri-state output circuits are both in a high-impedance state when the above-mentioned clock signal CLK is low-level, the latch circuit consisting of the above-mentioned inverter circuits INV5 and INV6 maintains the state before the above-mentioned precharging and then outputs.

When the clock signal CLK is made high-level, the nodes N1 and N2 are fixed at a binary level in the above-mentioned latch circuit of the first and second stages corresponding to asynchronous signal D. For instance, if the node N1 is high-level and the node N2 is low-level, P-channel MOSFET MP9 and N-channel MOSFET MN9 are in On state and P-channel MOSFET MP10 and N-channel MOSFET MN 8 are in OFF state. At that time, the high-level is output from the output circuit consisting of MOSFET MP9 and MN8, and the low-level is output from the output circuit consisting of MOSFET MP10 and MN9, thereby, the latch circuit consisting of inverter circuits INV5 and INV6 fetch the signals corresponding thereto and output a low-level from the output terminal Q. On the other hand, if the node N1 is low-level and the node N2 is high-level, a high level is output from the output terminal Q.

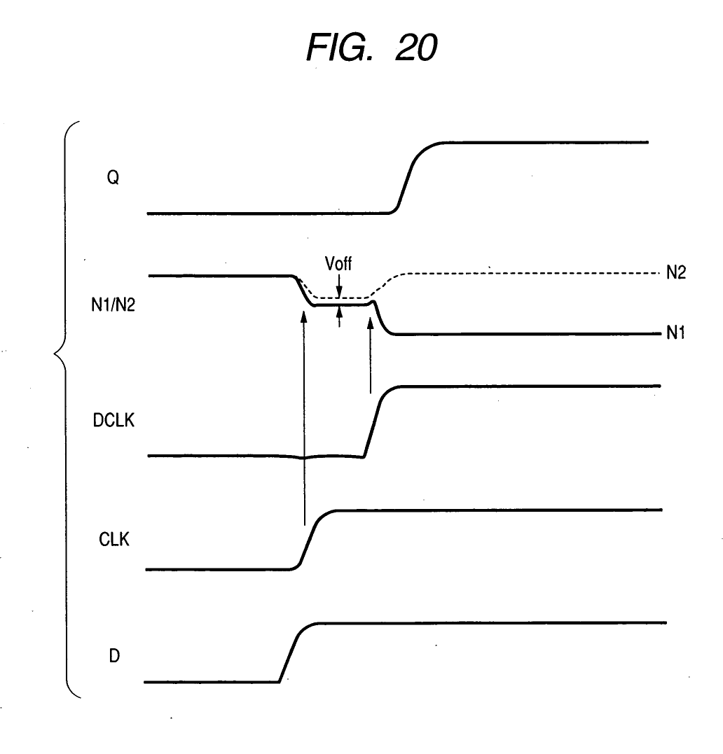

FIG. 20 illustrates a waveform diagram to explain the operation of the synchronous circuit shown in FIG. 19 in a metastable state. The asynchronous signal D is input almost simultaneously for activation of the clock signal CLK, for instance, even if balancing the current flow in the N-channel MOSFETs MN1 and MN2 makes a metastable state because of the level transition states being low-level to high-level, it is transmitted to the latch circuit nodes N1 and N2 of the second stage because the circuit is designed to generate an offset voltage Voff. A high-level of the delay signal DCLK of the clock signal CLK makes the latch circuit of the second stage initiate the amplifier operation and fixes the node N2 to logic high-level and node N1 to logic low-level corresponding to the above-mentioned offset voltage Voff. Therefore, if the state of the output latch circuit maintains the low-level output signal, the output terminal Q changes from low-level to high-level corresponding to the above-mentioned delay signal DCLK, and a synchronous output signal can be obtained. The logic output signal (Q) without such a metastable state is not necessarily a correct logical level. That is, in the synchronous circuit of this embodiment, there is a purpose in forming a logic output signal without a metastable state, and it is useful in preventing the aforementioned logic malfunction.

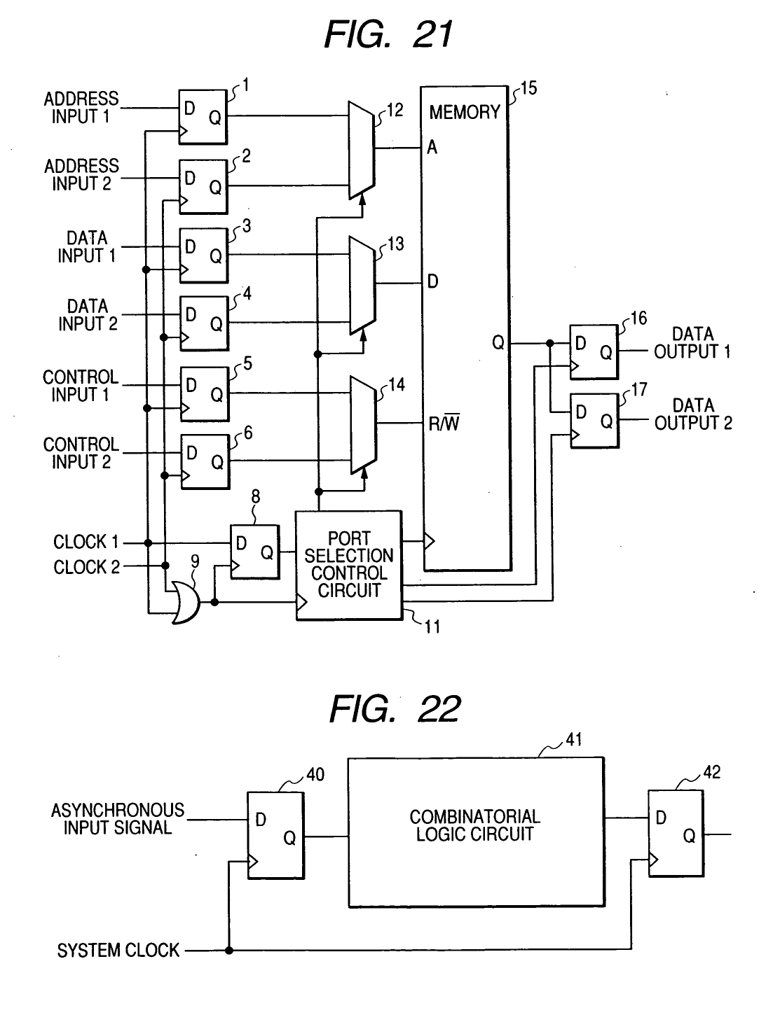

FIG. 21 is a block diagram illustrating another embodiment of an asynchronous multi-port memory using a synchronous circuit according to the present invention. Address input 1, data input 1, control input 1 are synchronized with the clock 1, and address input 2, data input 2, control input 2 are synchronized with the clock 2. When the clock 1 or clock 2 are input, the synchronous circuit 8 fixes which clock is input and, based on the signal, the port selection control circuit 11 generates the clock signal to operate the selectors 12-14 and the flip-flops 16 and 17. The detail of the port selection control circuit 11 is the same as the circuit shown in the aforementioned FIG. 6.

In the case where the conventional flip-flop circuit is used as a synchronous circuit 8, a conflict arises in the logic circuit when a metastable state (quasi-stable state) as previously mentioned is generated in the flip-flop circuit, thereby, the aforementioned malfunction is created. If the two-stage flip-flop circuit is used as shown in aforementioned FIG. 17, and one waits until the metastable state vanishes, the delay time will increase. In the case where the synchronous circuit is used as shown in aforementioned FIG. 19, it is possible to reduce the timing margin compared with the synchronous circuit using the latch circuit of the two stage configuration shown in FIG. 17, and a high speed asynchronous pseudo multi-port memory can be achieved. Therefore, in a high-speed memory, a highly integrated pseudo multi-port memory can be achieved compared with duplexed circuit multi-port memory, and cost reduction of semiconductor memory becomes possible.

FIG. 22 is a block diagram illustrating an embodiment of the present invention. In this embodiment, the asynchronous input signal and system clock are input to the synchronous circuit 40 shown in aforementioned FIGS. 18 and 19. Then, the output signal Q is supplied to the combinatorial logic circuit 41, and this output signal is fetched into the flip-flop circuit 42 which operates with the above-mentioned system clock. The basic configuration of the logic signal processing circuit consists of a combination with the unit of flip-flop FF-logic stage-flip-flop FF, and a clock pulse is supplied to the above-mentioned flip-flop FF. The signal maintained in the flip-flop FF placed on the input side of the logic stage is input into this logic stage by synchronizing with the clock pulse. In the logic stage, logic processing is executed corresponding to the input signal and transmitted to the input terminals of the flip-flop FF located on the output side. The flip-flop FF located on the output side synchronizes with the next clock pulse and maintains the fetching of the output signal at the above-mentioned logic stage. Thus, the logic sequence synchronized with the clock pulse is executed. When the synchronous circuit of this embodiment is used for fetching an asynchronous input signal, signal processing for an asynchronous input can be executed without delaying for one clock as shown in the case using the synchronous circuit as in FIG. 17. In this case, because the input signal being transmitted to the combinatorial logic circuit 41 is slightly delayed only for the delay time at the delay circuit DLY, a shorter signal delay at the logic stage should be designed in order to compensate for it.

Above we have illustrated the invention of the present inventors on the basis of the preferred embodiments. However, it is to be understood that the invention is not intended to be limited to the specific embodiment and variations may be made by one skilled in the art without departing from the scope of the invention. For instance, anything which achieves the aforementioned function may be used for a concrete configuration of the aforementioned event generating circuit and priority encoder. It is not necessary to allocate the chance of memory access equally to n ports. For instance, the memory access may always be executed from the microprocessor and the user logic, etc. with a high priority-rank, and the microprocessor and the user logic, etc. with a low priority-rank may be the one where access is permitted only with an empty state. Anything such as control devices executing display operation and direct memory access control devices, etc. may be used for the device executing memory access besides the above-mentioned microprocessor and user logic, etc.

In the aforementioned embodiment circuit shown in FIG. 19, the latch circuit of the first stage may have a size ratio which generates the aforementioned offset output voltage on the P-channel MOSFET side, and the input signal may be received by the P-channel MOSFET. In this case, the precharge level is made a low-level such as the ground voltage of the circuit. Therefore, the N-channel MOSFET is used for the switch MOSFET which transmits the output signal to the latch circuit of the second stage. Moreover, a CMOS switch, in which a P-channel MOSFET is connected in parallel with an N-channel MOSFET, may be used for this switch MOSFET. The latch circuit of the second stage may simply consist of amplifier circuits. For instance, a differential amplifier circuit may be used, which is made operation mode by a high-level of the clock signal CLK. In the case where such a differential circuit is used, the above-mentioned delay circuit DLY may be omitted. In the case where such a differential circuit is used, an output circuit is provided which converts the output signal into a high-level corresponding to the power supply voltage vdd and into a low-level corresponding to the ground voltage of the circuit. This invention provides a way to widely use various kinds of semiconductor integrated circuit devices employing asynchronous control circuits and the asynchronous multi-port memories that use them.

The effects obtained by the embodiments disclosed in the present invention are briefly explained as follows:

It is possible to realize asynchronous operation as an asynchronous control circuit and to remove the limitation on the number of ports performing, by the following steps of:
a) acknowledging a plurality of access request signals generated asynchronously to each other and a plurality of input signals corresponding to each of the above-mentioned plurality of access request signals,
b) being activated corresponding to at least one access request
c) selecting one access request from the one or more access requests in this activation state,
d) acknowledging the input signal corresponding thereto and transmitting the input signal in question to the circuit function block executing a predetermined circuit operation,
e) acknowledging the input signal corresponding to a non-executed access request after the end the operation corresponding to the input signal in question.

A multi-port memory without limitation on the number of ports in an asynchronous operation with a small area can be achieved by the following steps of:
a) providing an asynchronous control circuit and memory circuit in a semiconductor integrated circuit device,
b) activating the above-mentioned asynchronous control circuit corresponding to at least one access request by acknowledging a plurality of access request signals generated asynchronously to each other and a plurality of input signals corresponding to each of the above-mentioned plurality of access requests,
c) selecting one access request from the one or more access requests in the activation state,
d) acknowledging the input signal corresponding thereto and transmitting the input signal in question to the circuit function block executing a predetermined circuit operation,
e) acknowledging the input signal corresponding to a non-executed access request after the end the operation corresponding to the input signal in question.

1. An asynchronous control circuit, comprising the steps of:
acknowledging a plurality of access request signals and a plurality of input signals corresponding to each of said plurality of access request signals,
being activated corresponding to at least one access request of said plurality of access request signals,
acknowledging said input signal corresponding to one predetermined access request according to one or more access requests in the activating state,
transmitting the proper input signal to a circuit function block executing a predetermined circuit operation, and
acknowledging said input signal corresponding to a non-executed access request after the end of operation corresponding to the proper input signal.

2. An asynchronous control circuit according to claim 1, wherein said plurality of access request signals is a clock signal or timing signal which is independently generated asynchronously.

3. An asynchronous control circuit according to claim 2, comprising a priority setting circuit selecting one access request with high priority decided beforehand from among a plurality of access requests in said activating state.

4. An asynchronous control circuit according to claim 3, wherein
said asynchronous control circuit comprises a plurality of first flip-flop circuits, OR circuits, and third flip-flop circuits,
said plurality of access request signals are supplied individually to said plurality of first flip-flop circuits corresponding thereto as set input signals,
the output signal of said first flip-flop circuits is transmitted to said OR circuit and priority setting circuit,
the output signal of said OR circuit is transmitted to said third flip-flop circuit,
said third flip-flop circuit is set by the output signal of said OR circuit, and the set signal not only enables the output of said priority setting circuit, but also stops the transmission of the output signal of said first flip-flop circuit to said OR circuit,
said priority setting circuit selects one access request and resets said first flip-flop circuit corresponding to it, as well as transmits said input signal to said circuit function block, and
said third flip-flop circuit is reset corresponding to the timing of the end of the operation of said circuit function block.

5. An asynchronous control circuit according to claim 4, wherein
said priority setting circuit comprises a second flip-flop circuit which receives the output signal of said first flip-flop circuit except for the lowest priority,
said second flip-flop circuit fetches the output signal of said first flip-flop circuit according to the output signal of said OR circuit, and
the output signal of said second flip-flop circuit is used for deselection of the access request with a lower priority-rank.

6. A Semiconductor integrated circuit device comprises an asynchronous control circuit and a memory circuit, wherein
said asynchronous control circuit acknowledges a plurality of access request signals and a plurality of input signals corresponding to each of said plurality of access request signals, is activated corresponding to at least one access request of said plurality of access request signals, acknowledges said input signal corresponding to one predetermined access request according to one or more access requests in the activating state and transmits the proper input signal to said memory circuit, and acknowledges said input signal corresponding to a non-executed access request after the end of the operation corresponding to the proper input signal, and
said memory circuit is accessed through said asynchronous control circuit.

7. A Semiconductor integrated circuit device according to claim 6, furthermore comprising said plurality of input latches and output latches corresponding to a plurality of access request signals, wherein
the input signal corresponding to said accepted access requests, which is fetched into said output latch, is transmitted to a memory circuit, and
the output signal corresponding to said access requests is the one being fetched by said output latch circuit.

8. A Semiconductor integrated circuit device according to claim 7, wherein said plurality of access requests are clock signals or timing signals which are independently generated asynchronously.

9. A Semiconductor integrated circuit device according to claim 8, wherein said asynchronous control circuit comprises a priority setting circuit selecting one access request with high priority decided beforehand from among a plurality of access requests in said activation state.

10. A Semiconductor integrated circuit device according to claim 9, wherein
said asynchronous control circuit comprises a plurality of first flip-flop circuits, OR circuits, and third flip-flop circuits,
said plurality of access request signals are supplied individually to said plurality of first flip-flop circuits corresponding to them as set signals,
the output signal of said first flip-flop circuits is transmitted to said OR circuit and priority setting circuit,
the output signal of said OR circuit is transmitted to said third flip-flop circuit,
said third flip-flop circuit is set by the output signal of said OR circuit, and the set signal not only enables the output of said priority setting circuit, but also stops the transmission of the output signal of said first flip-flop circuit to said OR circuit,
said priority predetermined circuit selects one access request and resets said first flip-flop circuit corresponding to it, as well as transmits said input signal to said circuit memory circuit, and
said third flip-flop circuit is reset corresponding to the timing of the end of the operation of said memory circuit.

11. A Semiconductor integrated circuit device according to claim 10, wherein
said priority setting circuit comprises a second flip-flop circuit which acknowledges the output signal of said first flip-flop circuit except for the lowest priority,
said second flip-flop circuit fetches the output signal of said first flip-flop circuit according to the output signal of said OR circuit, and
the output signal of said second flip-flop circuit is used for deselection of the access request with the lower priority-rank.

12. A Semiconductor integrated circuit device according to claim 10, wherein
said asynchronous control circuit comprises a cycle time replica circuit of said memory circuit, and
said cycle time replica circuit acknowledges the output signal of said OR circuit and forms a reset signal of said third flip-flop circuit after passing the predetermined cycle time of said memory circuit.

13. A Semiconductor integrated circuit device according to claim 6, wherein said memory circuit is a static type RAM having one port.

14. A Semiconductor integrated circuit device according to claim 13, wherein said plurality of access request signals is three or more, and each one has a different frequency.

15. A Semiconductor integrated circuit device according to claim 14, comprising an address generating circuit which creates an address signal transmitted to said memory circuit corresponding to an access request signal selected by said asynchronous control circuit.

16. An asynchronous control circuit according to claim 5, wherein said second flip-flop circuit or third flip-flop circuit includes a first latch circuit, which creates a pair of output signals having an offset voltage in a metastable state, and an amplifier circuit, which amplifies the offset voltage of said output signal.

17. A Semiconductor integrated circuit device according to claim 11, wherein said second flip-flop circuit or third flip-flop circuit creates logic output having no metastable state.

18. A Semiconductor integrated circuit device according to claim 17, wherein said second flip-flop circuit or third flip-flop circuit includes a first latch circuit, which creates a pair of output signals having an offset voltage in a metastable state, and an amplifier circuit, which amplifies the offset voltage of said output signal.

19. A Semiconductor integrated circuit device according to claim 18, wherein said amplifier circuit has a pair of input terminals with differential configuration, which receives a pair of output signals of said first latch circuit, and includes a second latch circuit, which is operated by a delay signal of an operation timing signal of said first latch circuit.

20. A semiconductor integrated circuit device according to claim 18, wherein
said first latch circuit comprises:
a first CMOS inverter circuit consisting of a first N-channel MOSFET and a first P-channel MOSFET,
a second CMOS inverter circuit consisting of a second N-channel MOSFET and a second P-channel MOSFET,
a third N-channel MOSFET being connected in parallel to said first N-channel MOSFET, in which the logic signals of an asynchronous input signal and clock signal are inputted to a gate,
a fourth N-channel MOSFET supplying ground voltage of the circuit to the sources of said first and second N-channel MOSFETs,
a precharge MOSFET, and
a gate circuit forming said logic signal;
the input and output of said first CMOS inverter circuit and second CMOS inverter circuit are cross-connected to each other and joined to a pair of output terminals,
said precharge MOSFET is placed between said pair of output terminals and source voltage and, when the clock signal is in one of the levels, it becomes ON state and precharges said output terminals to the source voltage,
said fourth N-channel MOSFET becomes OFF state when said clock signal is in said one level, and it becomes ON state when it is in another level,
said gate circuit transmits a signal corresponding to an asynchronous input signal when said clock signal is in one level, and outputs a logic signal which makes said third MOSFET OFF state when it is in another level,
the conductance of said first N-channel MOSFET is made smaller corresponding to the aforementioned offset voltage compared to said second N-channel MOSFET.

21. A Semiconductor integrated circuit device according to claim 19, wherein
said second latch circuit comprises:
a third CMOS inverter circuit
a fourth CMOS inverter circuit,
a fifth N-channel MOSFET supplying ground voltage of the circuit to the source of the N-channel MOSFET constituting said third and fourth CMOS inverter circuits,
a switch MOSFET fetching a pair of output signals from said first latch circuit;
the input and output of said first CMOS inverter circuit and second CMOS inverter circuit are cross-connected to each other and have a pair of I/O terminals,
said switch MOSFET becomes ON state when said delay signal is in one level, and connects a pair of output terminals of said first latch circuit with a pair of I/O terminals of the second latch circuit,
said fifth N-channel MOSFET becomes ON state lagging behind the output signal of said first latch circuit because of said delay signal.

22. A Semiconductor integrated circuit device according to claim 21, wherein said third latch circuit maintains a pair of output signals of said second latch circuit when said clock signal is in one level.

23. A Semiconductor integrated circuit device, comprising:
a first latch circuit forming a pair of output signals with an offset voltage in a metastable state acknowledging an asynchronous signal and clock signal,
an amplifier circuit which amplifies an offset voltage of said output signal,
a synchronous circuit obtaining a synchronized output signal with said clock signal through said amplifier circuit.

24. A Semiconductor integrated circuit device according to claim 23, wherein
said first latch circuit comprises:
a first CMOS inverter circuit consisting of a first N-channel MOSFET and a first P-channel MOSFET,
a second CMOS inverter circuit consisting of a second N-channel MOSFET and a second P-channel MOSFET,
a third N-channel MOSFET being connected in parallel to said first N-channel MOSFET, in which the logic signals of an asynchronous input signal and clock signal are inputted to a gate,
a fourth N-channel MOSFET supplying ground voltage of the circuit to the sources of said first and second N-channel MOSFETs,
a precharge MOSFET, and
a gate circuit forming said logic signal;
the input and output of said first CMOS inverter circuit and second CMOS inverter circuit are cross-connected to each other and joined to a pair of output terminals,
said precharge MOSFET is placed between said pair of output terminals and source voltage and, when the clock signal is in one of the levels, it becomes ON state and precharges said output terminals to the source voltage,
said fourth N-channel MOSFET becomes OFF state when said clock signal is in said one level, and it becomes ON state when it is in another level,
said gate circuit transmits a signal corresponding to an asynchronous input signal when said clock signal is in one level, and outputs a logic signal which makes said third MOSFET OFF state when it is in another level,
the conductance of said first N-channel MOSFET is made smaller corresponding to the aforementioned offset voltage compared to said second N-channel MOSFET.

25. A Semiconductor integrated circuit device according to claim 23, wherein said amplifier circuit has a pair of input terminals with differential configuration, which receive a pair of output signals of said first latch circuit, and includes a second latch circuit, which is operated by a delay signal of an operation timing signal of said first latch circuit.

26. A Semiconductor integrated circuit device according to claim 25, wherein
said second latch circuit comprises:
a third CMOS inverter circuit
a fourth CMOS inverter circuit,
a fifth N-channel MOSFET supplying ground voltage of the circuit to the source of the N-channel MOSFET constituting said third and fourth CMOS inverter circuits,
a switch MOSFET fetching a pair of output signals from said first latch circuit;
the input and output of said first CMOS inverter circuit and second CMOS inverter circuit are cross-connected to each other and have a pair of I/O terminals,
said switch MOSFET becomes ON state when said delay signal is in one level, and connects a pair of output terminals of said first latch circuit with a pair of I/O terminals of the second latch circuit,
said fifth N-channel MOSFET becomes ON state lagging behind the output signal of said first latch circuit because of said delay signal.

27. A Semiconductor integrated circuit device according to claim 26, comprising
fifth and sixth inverter circuits individually acknowledging the signals of a pair of terminals of said second latch circuit,
seventh and eighth inverter circuits individually acknowledging the output signals of said fifth and sixth inverter circuits,
a first tri-state output circuit comprising an N-channel MOSFET in which the output signal of said fifth inverter circuit is supplied to the gate, and a P-channel MOSFET in which the output signal of said eighth inverter circuit is supplied to the gate,
a second tri-state output circuit comprising an N-channel MOSFET in which the output signal of said sixth inverter circuit is supplied to the gate, and a P-channel MOSFET in which the output signal of said seventh inverter circuit is supplied to the gate,
moreover, a third latch circuit connecting a pair of I/O terminals to the output terminals of said first output circuit and second output circuit.
